(19) United States
(12) Patent Application Publication
(10) Pub. No.: US 2025/0185349 A1
(43) Pub. Date: Jun. 5, 2025

(54) SEMICONDUCTOR DEVICE

(71) Applicant: FUJI ELECTRIC CO., LTD., Kanagawa (JP)

(72) Inventors: Motoyoshi KUBOUCHI, Matsumoto-city (JP); Makoto SHIMOSAWA, Matsumoto-city (JP)

(21) Appl. No.: 19/037,265

(22) Filed: Jan. 26, 2025

Related U.S. Application Data
(63) Continuation of application No. PCT/JP2023/041828, filed on Nov. 21, 2023.

(30) Foreign Application Priority Data
Feb. 7, 2023 (JP) 2023-016610

(51) Int. Cl. H10D 84/00; H10D 8/00; H10D 12/00; H10D 62/10; H10D 62/53; H10D 62/60; H10D 64/23

(52) U.S. Cl. CPC H10D 84/161; H10D 8/422; H10D 12/481; H10D 62/105; H10D 62/53; H10D 62/60; H10D 64/232

(57) ABSTRACT

Provided is a semiconductor device comprising a diode portion that is arranged side by side with a transistor portion, wherein the transistor portion includes: a first contact portion in which a first mesa portion among a plurality of mesa portions and a metal electrode are in contact with each other; and a second contact portion in which a second mesa portion among the plurality of mesa portions, which is arranged further apart from the diode portion than the first mesa portion, and the metal electrode is in contact with each other, and a lower end of the first contact portion is arranged above a lower end of the second contact portion.

The contents of the following patent application(s) are incorporated herein by reference:
NO. 2023-016610 filed in JP on Feb. 7, 2023
NO. PCT/JP2023/041828 filed in WO on Nov. 21, 2023.

### BACKGROUND

### 1. Technical Field

The present invention relates to a semiconductor device.

### 2. Related Art

Known is a structure in which, in a semiconductor device having a transistor portion and a diode portion, a carrier lifetime is adjusted by partially forming a defect region in the diode portion and the transistor portion (for example, refer Patent document 1). Also known is a structure in which, in a semiconductor device, an electrode and a semiconductor substrate are connected by a contact with a trench shape (for example, refer to Patent document 2).
Patent Document 1: WO 2021/145079
Patent Document 2: Japanese Patent No. 7085975

### BRIEF DESCRIPTION OF THE DRAWINGS

FIG. 1 is a top view illustrating an example of a semiconductor device 100 according to one embodiment of the present invention.

FIG. 2 shows an enlarged view of a region D in FIG. 1.

FIG. 3 shows an example of a cross section e-e in FIG. 2.

FIG. 4A is an enlarged view of a vicinity of a first mesa portion 61, a second mesa portion 62, and a third mesa portion 63.

FIG. 4B is an enlarged view of a vicinity of the first mesa portion 61, the second mesa portion 62, and the third mesa portion 63.

FIG. 5 shows an example of a cross section f-f in FIG. 2.

FIG. 6A is an enlarged view of a vicinity of the first mesa portion 61, the second mesa portion 62, and the third mesa portion 63 shown in FIG. 5.

FIG. 6B is an enlarged view of a vicinity of the first mesa portion 61, the second mesa portion 62, and the third mesa portion 63 shown in FIG. 5.

FIG. 7A shows an example of a doping concentration distribution in the line a-a and the line b-b in FIG. 6A.

FIG. 7B shows an example of a doping concentration distribution in the line a-a and the line b-b in FIG. 6B.

FIG. 8A is an enlarged view that is in the vicinity of the first contact portion 211.

FIG. 8B is an enlarged view that is in the vicinity of the second contact portion 212.

FIG. 9A shows another example of the cross section e-e.

FIG. 9B shows another example of the cross section e-e.

FIG. 10 shows an exemplary arrangement of an adjustment region 201 and a non-adjustment region 202 in a top view.

FIG. 11 shows another example of the cross section e-e.

FIG. 12 shows another example of the cross section e-e.

FIG. 13 shows another example of the cross section e-e.

FIG. 14 shows another example of the cross section e-e.

FIG. 15A shows another example of the cross section e-e.

FIG. 15B shows another example of the cross section e-e.

FIG. 16 shows another example of the cross section e-e.

FIG. 17 is an enlarged view of a vicinity of the first mesa portion 61, the second mesa portion 62, and the third mesa portion 63 shown in FIG. 5.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solution of the invention.

As used herein, one side in a direction parallel to a depth direction of a semiconductor substrate is referred to as “upper” and another side is referred to as “lower”. One surface of two principal surfaces of a substrate, a layer or another member is referred to as an upper surface, and another surface is referred to as a lower surface. “Upper” and “lower” directions are not limited to a direction of gravity, or a direction in which a semiconductor device is mounted.

In the present specification, technical matters may be described using orthogonal coordinate axes of the X axis, the Y axis, and the Z axis. The orthogonal coordinate axes merely specify relative positions of components, and do not limit a specific direction. For example, the Z axis is not limited to indicate the height direction with respect to the ground. It should be noted that the +Z axis direction and the −Z axis direction are directions opposite to each other. If the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as a depth direction. In addition, in the present specification, a direction parallel to the upper surface and the lower surface of the semiconductor substrate may be referred to as a horizontal direction, including the X axis direction and the Y axis direction.

A region from a center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of a doping region doped with impurities is described as a P type or an N type. In the present specification, the impurities may particularly mean either donors of the N type or acceptors of the P type, and may be described as dopants. In the present specification, doping means introducing the donor or the acceptor into the semiconductor substrate and turning it into a semiconductor presenting a conductivity type of the N type or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is ND and the acceptor concentration is NA, the net doping concentration at any position is given as ND-NA. In the present specification, the net doping concentration may be simply described as the doping concentration.

The donor has a function of supplying electrons to a semiconductor. The acceptor has a function of receiving electrons from the semiconductor. The donor and the acceptor are not limited to the impurities themselves. For example, a VOH defect in which a vacancy (V), oxygen (O), and hydrogen (H) present in the semiconductor are attached together functions as the donor which supplies the electrons. The hydrogen donor may be a donor obtained by the combination of at least a vacancy (V) and hydrogen (H). Alternatively, interstitial Si—H which is a combination of interstitial silicon (Si-i) and hydrogen in a silicon semiconductor also functions as the donor that supplies electrons. In the present specification, the VOH defect or interstitial Si—H may be referred to as a hydrogen donor.

In the semiconductor substrate in the present specification, bulk donors of the N type are distributed throughout. The bulk donor is a dopant donor substantially uniformly contained in an ingot during the manufacture of the ingot from which the semiconductor substrate is made. The bulk donor in the present example is an element other than hydrogen. The bulk donor dopant is, for example, phosphorous, antimony, arsenic, selenium, or sulfur, but the invention is not limited to these. The bulk donor in the present example is phosphorous. The bulk donor is also contained in a region of the P type. The semiconductor substrate may be a wafer cut out from a semiconductor ingot, or may be a chip obtained by singulating the wafer. The semiconductor ingot may be manufactured by either a Czochralski method (CZ method), a magnetic field applied

Czochralski method (MCZ method), or a float zone method (FZ method). The ingot in the present example is manufactured by the MCZ method. An oxygen concentration contained in the substrate manufactured by the MCZ method is 1×10¹⁷ to 7×10¹⁷/cm³. The oxygen concentration contained in the substrate manufactured by the FZ method is 1×10¹⁵ to 5×10¹⁶/cm³. When the oxygen concentration is high, hydrogen donors tend to be easily generated. The bulk donor concentration may use a chemical concentration of bulk donors distributed throughout the semiconductor substrate, or may be a value between 90% and 100% of the chemical concentration. In addition, as the semiconductor substrate, a non-doped substrate not containing a dopant such as phosphorous may be used. In that case, the bulk donor concentration (DO) of the non-doped substrate is, for example, from 1×10¹⁰/cm³ or more and to 5×10¹²/cm³ or less. The bulk donor concentration (DO) of the non-doped substrate is preferably 1×10¹¹/cm³ or more. The bulk donor concentration (DO) of the non-doped substrate is preferably 5×10¹²/cm³ or less. Each concentration in the present invention may be a value at room temperature. As an example, a value at 300K (Kelvin) (about 26.9 degrees C.) may be used as the value at room temperature.

In the present specification, a description of a P+ type or an N+ type means a higher doping concentration than that of the P type or the N type, and a description of a P-type or an N-type means a lower doping concentration than that of the P type or the N type. In addition, in the present specification, a description of a P++ type or an N++ type means a higher doping concentration than that of the P+ type or the N+ type. In the present specification, a unit system is the SI base unit system unless otherwise noted. Although a unit of length may be indicated by cm, it may be converted to meters (m) before calculations.

A chemical concentration in the present specification refers to an atomic density of an impurity measured regardless of an electrical activation state. The chemical concentration can be measured by, for example, secondary ion mass spectrometry (SIMS). The net doping concentration described above can be measured by capacitance-voltage profiling (CV profiling). In addition, a carrier concentration measured by spreading resistance profiling (SRP method) may be set as the net doping concentration. The carrier concentration measured by the CV profiling or the SRP method may be a value in a thermal equilibrium state. In addition, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

When a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping. In the present specification, atoms/cm³ or/cm³ is used to indicate a concentration per unit volume. This unit is used for a concentration of a donor or an acceptor in a semiconductor substrate, or a chemical concentration. A notation of atoms may be omitted.

The carrier concentration measured by the SRP method may be lower than that of the concentration of the donor or the acceptor. In a range where a current flows when a spreading resistance is measured, carrier mobility of the semiconductor substrate may be lower than a value in a crystalline state. The decrease in the carrier mobility occurs when carriers are scattered due to disorder (disorder) of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

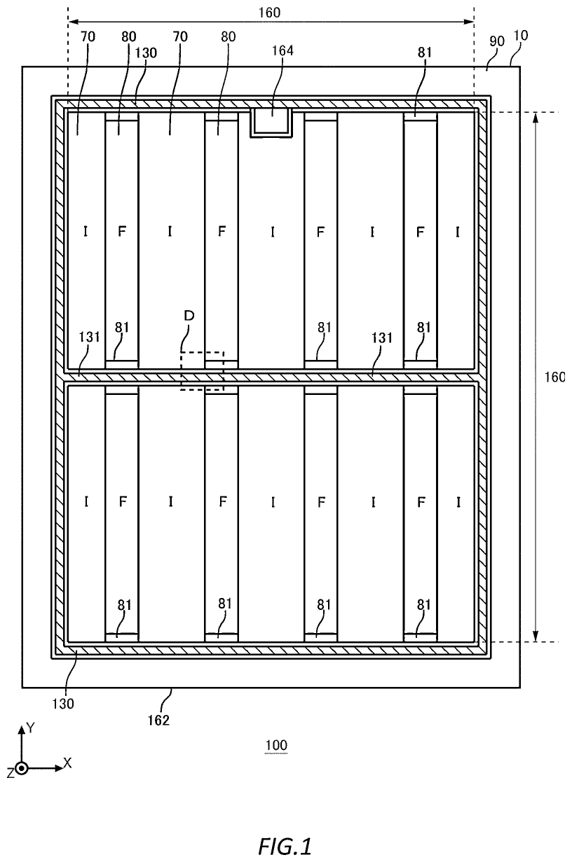

FIG. 1 is a top view illustrating an example of a semiconductor device 100 according to one embodiment of the present invention. FIG. 1 shows a position of each member projected onto an upper surface of a semiconductor substrate 10. FIG. 1 shows merely some members of the semiconductor device 100, and omits another member.

The semiconductor device 100 includes the semiconductor substrate 10. The semiconductor substrate 10 is a substrate which is formed of a semiconductor material. As an example, the semiconductor substrate 10 is a silicon substrate. The semiconductor substrate 10 has an end side 162 in a top view. When simply referred to as the top view in the present specification, it means that the semiconductor substrate 10 is viewed from an upper surface side. The semiconductor substrate 10 in the present example has two sets of end sides 162 opposite to each other in a top view. In FIG. 1, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region where a main current flows in a depth direction between the upper surface and a lower surface of the semiconductor substrate 10 when the semiconductor device 100 operates. An emitter electrode is provided above the active portion 160, but is omitted in FIG. 1. The active portion 160 may refer to a region that overlaps with the emitter electrode in the top view. In addition, a region sandwiched between active portions 160 in a top view may also be included in the active portion 160.

The active portion 160 is provided with a transistor portion 70 including a transistor element such as an insulated gate bipolar transistor (IGBT) and a diode portion 80 including a diode element such as a freewheeling diode (FWD). In the example in FIG. 1, each of the transistor portions 70 and each of the diode portions 80 are arranged alternately along a predetermined first direction (an X axis direction in the present example) on the upper surface of the semiconductor substrate 10. The semiconductor device 100 in the present example is a reverse conduction type IGBT (RC-IGBT). A boundary region is arranged between the transistor portion 70 and the diode portion 80 in the X axis direction, but is omitted in FIG. 1.

In FIG. 1, a region where each of the transistor portions 70 is arranged is indicated by a symbol “I”, and a region where each of the diode portions 80 is arranged is indicated by a symbol

“F”. In the present specification, a direction different from the first direction in the top view may be referred to as a second direction (the Y axis direction in FIG. 1). The second direction may be a direction perpendicular to the first direction. Each of the transistor portion 70 and the diode portion 80 may have a longitudinal length in the second direction. In other words, a length of the transistor portion 70 in the Y axis direction is greater than a width in the X axis direction. Similarly, a length of the diode portion 80 in the Y axis direction is greater than a width in the X axis direction. The second direction of the transistor portion 70 and the diode portion 80 may be the same as a longitudinal direction of each trench portion and a longitudinal direction of the mesa portion described below.

Each of the diode portions 80 includes a cathode region of an N+ type in a region in contact with the lower surface of the semiconductor substrate 10. In the present specification, a region where the cathode region is provided is referred to as the diode portion 80. In other words, the diode portion 80 is a region overlapping the cathode region in a top view. On the lower surface of the semiconductor substrate 10, a collector region of a P+ type may be provided in a region other than the cathode region. In the present specification, the diode portion 80 may also include an extension region 81 where the diode portion 80 extends to a gate runner described below in the Y axis direction. The collector region is provided on a lower surface of the extension region 81.

The transistor portion 70 has the collector region of the P+ type in a region in contact with the lower surface of the semiconductor substrate 10. In addition, in the transistor portion 70, an emitter region of an N type, a base region of the P type, and a gate structure having a gate conductive portion and a gate dielectric film are periodically arranged on the upper surface side of the semiconductor substrate 10.

The semiconductor device 100 may include one or more pads above the semiconductor substrate 10. The semiconductor device 100 in the present example has a gate pad 164. The semiconductor device 100 may have a pad such as an anode pad, a cathode pad, and a current detection pad. Each pad is arranged in a vicinity of the end side 162. The vicinity of the end side 162 refers to a region between the end side 162 and the emitter electrode in a top view. When the semiconductor device 100 is mounted, each pad may be connected to an external circuit via a wiring line such as a wire.

A gate potential is applied to the gate pad 164. The gate pad 164 is electrically connected to a conductive portion of a gate trench portion of the active portion 160. The semiconductor device 100 includes a gate runner that connects the gate pad 164 and the gate trench portion. In FIG. 1, the gate runner is hatched with diagonal lines.

The gate runner in the present example has an outer circumferential gate runner 130 and an active-side gate runner 131. The outer circumferential gate runner 130 is arranged between the active portion 160 and the end side 162 of the semiconductor substrate 10 in a top view. The outer circumferential gate runner 130 in the present example encloses the active portion 160 in a top view. A region enclosed by the outer circumferential gate runner 130 in a top view may be defined as the active portion 160. In addition, a well region is formed below the gate runner. The well region is a P type region having a higher concentration than the base region described below, and is formed from the upper surface of the semiconductor substrate 10 to a position deeper than that of the base region. A region enclosed by the well region in a top view may be defined as the active portion 160.

The outer circumferential gate runner 130 is connected to the gate pad 164. The outer circumferential gate runner 130 is arranged above the semiconductor substrate 10. The outer circumferential gate runner 130 may be a metal wiring including such as aluminum, or a wiring formed of a semiconductor such as polysilicon doped with an impurity.

The active-side gate runner 131 is provided in the active portion 160. Providing the active-side gate runner 131 in the active portion 160 can reduce a variation in a wiring line length from the gate pad 164 for each region of the semiconductor substrate 10.

The outer circumferential gate runner 130 and the active-side gate runner 131 are connected to the gate trench portion of the active portion 160. The outer circumferential gate runner 130 and the active-side gate runner 131 are arranged above the semiconductor substrate 10. The outer circumferential gate runner 130 and the active-side gate runner 131 may be a metal wiring including such as aluminum, or a wiring formed of a semiconductor such as polysilicon doped with an impurity.

The active-side gate runner 131 may be connected to the outer circumferential gate runner 130. The active-side gate runner 131 in the present example is provided extending in the X axis direction so as to cross the active portion 160 substantially at the center of the Y axis direction from one outer circumferential gate runner 130 to another outer circumferential gate runner 130 which sandwich the active portion 160. When the active portion 160 is divided by the active-side gate runner 131, the transistor portions 70 and the diode portions 80 may be alternately arranged in the X axis direction in each divided region.

The semiconductor device 100 may include a temperature sensing portion (not shown) that is a PN junction diode formed of polysilicon or the like, and a current detection portion (not shown) that simulates an operation of the transistor portion provided in the active portion 160.

The semiconductor device 100 in the present example includes an edge termination structure portion 90 between the active portion 160 and the end side 162 in a top view. The edge termination structure portion 90 in the present example is arranged between the outer circumferential gate runner 130 and the end side 162. The edge termination structure portion 90 reduces electric field strength on the upper surface side of the semiconductor substrate 10. The edge termination structure portion 90 may include at least one of a guard ring, a field plate, or a RESURF which are annularly provided enclosing the active portion 160.

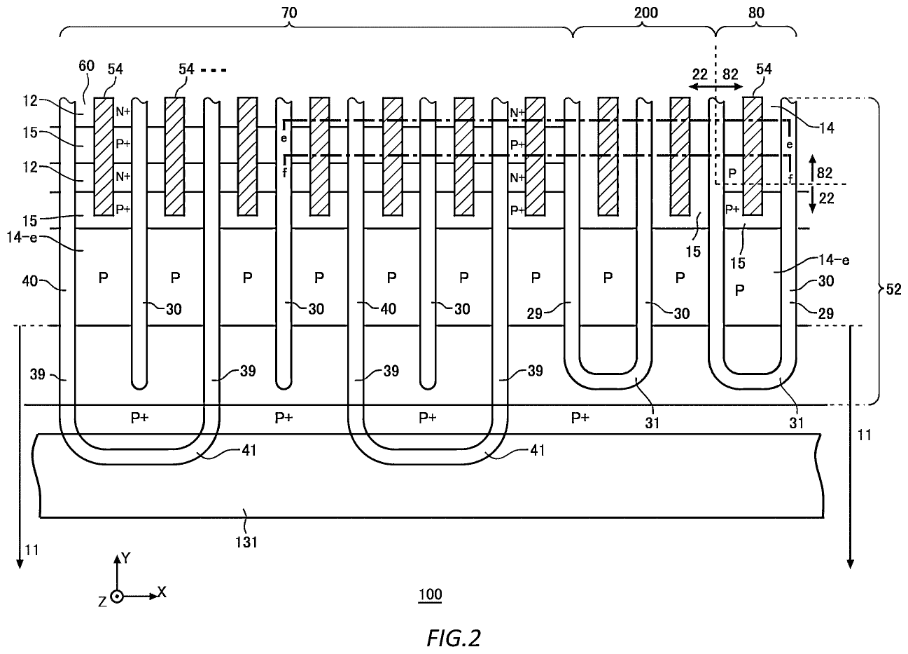

FIG. 2 illustrates an enlarged view of a region D in FIG. 1. The region D is a region including a transistor portion 70, a diode portion 80, and an active-side gate runner 131. Although omitted in FIG. 1, a boundary region 200 is arranged between the transistor portion 70 and the diode portion 80 in the X axis direction. A semiconductor device 100 in the present example includes a gate trench portion 40, a dummy trench portion 30, a well region 11, an emitter region 12, a base region 14, and a contact region 15 which are provided inside the upper surface side of a semiconductor substrate 10. The gate trench portion 40 and the dummy trench portion 30 are each one example of a trench portion. In addition, the semiconductor device 100 in the present example includes an emitter electrode 52 and the active-side gate runner 131 that are provided on or above the upper surface of the semiconductor substrate 10. The emitter electrode 52 is an example of a metal electrode. The emitter electrode 52 and the active-side gate runner 131 are provided in isolation from each other.

An interlayer dielectric film is provided between the emitter electrode 52 and the active-side gate runner 131, and the upper surface of the semiconductor substrate 10, but the interlayer dielectric film is omitted in FIG. 2. In the interlayer dielectric film in the present example, a contact hole 54 is provided penetrating the interlayer dielectric film. In FIG. 2, each contact hole 54 is hatched with the diagonal lines.

The emitter electrode 52 is provided above the gate trench portion 40, the dummy trench portion 30, the well region 11, the emitter region 12, the base region 14, and the contact region 15. The emitter electrode 52 is in contact with the emitter region 12, the contact region 15, and the base region 14 at the upper surface of the semiconductor substrate 10, through the contact hole 54. In addition, the emitter electrode 52 is connected to a dummy conductive portion in the dummy trench portion 30 through the contact hole provided in the interlayer dielectric film. The emitter electrode 52 may be connected to the dummy conductive portion of the dummy trench portion 30 at an edge of the dummy trench portion 30 in the Y axis direction. The dummy conductive portion of the dummy trench portion 30 may not be connected to the emitter electrode 52 and a gate conductive portion, and may be controlled to be at potential different from potential of the emitter electrode 52 and potential of the gate conductive portion.

The active-side gate runner 131 is connected to the gate trench portion 40 through the contact hole provided in the interlayer dielectric film. The active-side gate runner 131 may be connected to a gate conductive portion of the gate trench portion 40 at an edge portion 41 of the gate trench portion 40 in the Y axis direction. The active-side gate runner 131 is not connected to the dummy conductive portion in the dummy trench portion 30.

The emitter electrode 52 is formed of a material including a metal. FIG. 2 shows a range where the emitter electrode 52 is provided. For example, at least a part of a region of the emitter electrode 52 is formed of aluminum or an aluminum-silicon alloy, for example, a metal alloy such as AlSi, AlSiCu. The emitter electrode 52 may have a barrier metal formed of titanium, a titanium compound, or the like below a region formed of aluminum or the like. Further, a plug portion, which is formed by embedding tungsten or the like so as to be in contact with the barrier metal and aluminum or the like, may be included in the contact hole.

The well region 11 is provided overlapping the active-side gate runner 131. The well region 11 is provided so as to extend with a predetermined width even in a range not overlapping the active-side gate runner 131. The well region 11 in the present example is provided apart from an end of the contact hole 54 in the Y axis direction toward the active-side gate runner 131 side. The well region 11 is a region of a second conductivity type having a higher doping concentration than that of the base region 14. The base region 14 of the present example is a P type, and the well region 11 is a P+ type.

Each of the transistor portion 70, the diode portion 80, and the boundary region 200 includes a plurality of trench portions arranged in the first direction. In the transistor portion 70 of the present example, one or more gate trench portions 40 and one or more dummy trench portions 30 are alternately provided along the first direction. In the diode portion 80 of the present example, the plurality of dummy trench portions 30 are provided along the first direction.

In the diode portion 80 in the present example, the gate trench portion 40 is not provided. In the boundary region 200 of the present example, the plurality of dummy trench portions 30 are provided along the first direction. In the boundary region 200 of the present example, the gate trench portion 40 is not provided.

The gate trench portion 40 of the present example may have two linear portions 39 extending along the second direction perpendicular to the first direction (portions of a trench that are linear along the second direction), and the edge portion 41 connecting the two linear portions 39. The second direction in FIG. 2 is the Y axis direction.

At least a part of the edge portion 41 is preferably provided in a curved shape in a top view. By connecting between end portions of the two linear portions 39 in the Y axis direction by the edge portion 41, it is possible to reduce the electric field strength at the end portions of the linear portions 39.

In the transistor portion 70, the dummy trench portions 30 are provided between the respective linear portions 39 of the gate trench portions 40. Between the respective linear portions 39, one dummy trench portion 30 may be provided, or a plurality of dummy trench portions 30 may be provided. The dummy trench portion 30 may have a linear shape extending in the second direction, or may have linear portions 29 and an edge portion 31 similar to the gate trench portion 40. The semiconductor device 100 shown in FIG. 2 includes both of the linear dummy trench portion 30 having no edge portion 31, and the dummy trench portion 30 having the edge portion 31.

A diffusion depth of the well region 11 may be deeper than the depth of the gate trench portion 40 and the dummy trench portion 30. The end portions in the Y axis direction of the gate trench portion 40 and the dummy trench portion 30 are provided in the well region 11 in a top view. In other words, the bottom portion in a depth direction of each trench portion is covered with the well region 11 at the end portion in the Y axis direction of each trench portion. With this configuration, the electric field strength on the bottom portion of each trench portion can be reduced.

A mesa portion 60 is provided between the respective trench portions in the first direction. The mesa portion 60 refers to a region sandwiched between the trench portions inside the semiconductor substrate 10. As an example, an upper end of the mesa portion 60 is the upper surface of the semiconductor substrate 10. A depth position of a lower end of the mesa portion 60 is the same as a depth position of a lower end of the trench portion. The mesa portion 60 of the present example is provided extending in the second direction (the Y axis direction) along the trench, on the upper surface of the semiconductor substrate 10. The mesa portion 60 of the transistor portion 70, the mesa portion 60 of the diode portion 80, and the mesa portion 60 of the boundary region 200 may have a structure different from one another. When it is simply referred to as a mesa portion 60 in the present specification, it refers to the mesa portion 60 of the transistor portion 70, the mesa portion 60 of the diode portion 80, and the mesa portion 60 of the boundary region 200, respectively.

In each mesa portion 60, the base region 14 is provided. A region, which is arranged closest to the active-side gate runner 131, of the base region 14 exposed on the upper surface of the semiconductor substrate 10 in the mesa portion 60 is defined as a base region 14-e. While FIG. 2 shows the base region 14-e arranged at one end portion of each mesa portion in the second direction, the base region 14-e is also arranged at another end portion of each mesa portion. Each mesa portion may be provided with at least one of the emitter region 12 of a first conductivity type, and the contact region 15 of the second conductivity type in a region sandwiched between the base regions 14-e in a top view. The emitter region 12 in the present example is the N+ type, and the contact region 15 is the P+ type. The emitter region 12 and the contact region 15 may be provided between the base region 14 and the upper surface of the semiconductor substrate 10 in the depth direction.

The mesa portion 60 of the transistor portion 70 has the emitter regions 12 exposed on the upper surface of the semiconductor substrate 10. The emitter region 12 is provided in contact with the gate trench portion 40. The mesa portion 60 in contact with the gate trench portion 40 may be provided with the contact region 15 exposed on the upper surface of the semiconductor substrate 10.

Each of the contact region 15 and the emitter region 12 in the mesa portion 60 is provided from one trench portion to another trench portion in the X axis direction. As an example, the contact region 15 and the emitter region 12 of the mesa portion 60 are alternately arranged along the second direction of the trench portion (the Y axis direction).

In another example, the contact region 15 and the emitter region 12 of the mesa portion 60 may be provided in a stripe pattern along the second direction of the trench portion (the Y axis direction). For example, the emitter region 12 is provided in a region in contact with the trench portion, and the contact region 15 is provided in a region sandwiched between the emitter regions 12.

The mesa portions 60 of the diode portion 80 and the boundary region 200 are not provided with the emitter region 12. The base region 14 and the contact region 15 may be provided on the upper surfaces of the mesa portions 60 of the diode portion 80 and the boundary region 200. In the region sandwiched between the base regions 14-e on the upper surface of the mesa portion 60, the contact region 15 may be provided in contact with each base region 14-e.

The base region 14 may be provided in a region sandwiched between the contact regions 15 on the upper surface of the mesa portion 60 of the diode portion 80. The base region 14 may be arranged in the entire region sandwiched between the contact regions 15. The mesa portion 60 of the boundary region 200 may have a structure that is the same as or different from that of the mesa portion 60 of the diode portion 80. In the mesa portion 60 of the boundary region 200 in the present example, a contact region 15 is provided in the entire region that is sandwiched between the base regions 14-e. In other words, an area of the contact region 15 of the mesa portion 60 of the boundary region 200 may be greater than an area of the contact region 15 of the mesa portion 60 of the diode portion 80. In this case, a hole in the semiconductor substrate 10 can be easily extracted to the emitter electrode 52 via the mesa portion 60 of the boundary region 200.

In another example, the mesa portion 60 of the boundary region 200 may be a P type impurity region having a doping concentration approximately the same as that of the base region 14 of the transistor portion 70 or lower than that of the base region 14. The P type impurity region may occupy the entire mesa portion 60 of the boundary region 200, or the mesa portion 60 of the boundary region 200 may be provided with another region. By providing an impurity region of a P type in the mesa portion 60 of the boundary region 200, which has a doping concentration lower than that of the base region 14, implantation of holes from the mesa portion 60 of the boundary region 200 can be reduced, and a reverse recovery loss can be reduced.

In addition, in the mesa portion 60 of the boundary region 200, an impurity region of an N type may be provided, which has a doping concentration approximately the same as that of the emitter region 12 or lower than that of the emitter region 12. Note that in that case, the boundary region 200 is not provided with the gate trench portion 40. In addition, the trench portion at a boundary between the transistor portion 70 and the boundary region 200 is a dummy trench portion 30. In the mesa portion 60 of the boundary region 200, the impurity region of the N type is not in contact with the gate trench portion 40, and therefore a current that is greater than that of the transistor portion 70 does not flow into the boundary region 200. In this way, the implantation of the holes from the mesa portion 60 of the boundary region 200 can be reduced, and the reverse recovery loss can be reduced.

On the upper side of each mesa portion 60, the contact hole 54 is provided. The contact hole 54 is arranged in the region sandwiched between the base regions 14-e. The contact hole 54 in the present example is provided above respective regions of the contact region 15, the base region 14, and the emitter region 12. The contact hole 54 is not provided in regions corresponding to the base region 14-e and the well region 11. The contact hole 54 may be arranged at the center of the mesa portion 60 in the first direction (the X axis direction).

In the diode portion 80, a cathode region 82 of the N+ type is provided in a region in direct contact with the lower surface of the semiconductor substrate 10. On the lower surface of the semiconductor substrate 10, a collector region of the P+ type 22 may be provided in a region where the cathode region 82 is not provided. The cathode region 82 and a collector region 22 are provided between a lower surface 23 of the semiconductor substrate 10 and a buffer region 20. In

FIG. 2, a boundary between the cathode region 82 and the collector region 22 is indicated by a dotted line.

The cathode region 82 is arranged apart from the well region 11 in the Y axis direction. With this configuration, the distance between a region of a P type (the well region 11) having a comparatively high doping concentration and formed up to the deep position, and the cathode region 82 is ensured, so that the breakdown voltage can be improved. The end portion in the Y axis direction of the cathode region 82 in the present example is arranged farther apart from the well region 11 than the end portion in the Y axis direction of the contact hole 54. In another example, the end portion in the Y axis direction of the cathode region 82 may be arranged between the well region 11 and the contact hole 54.

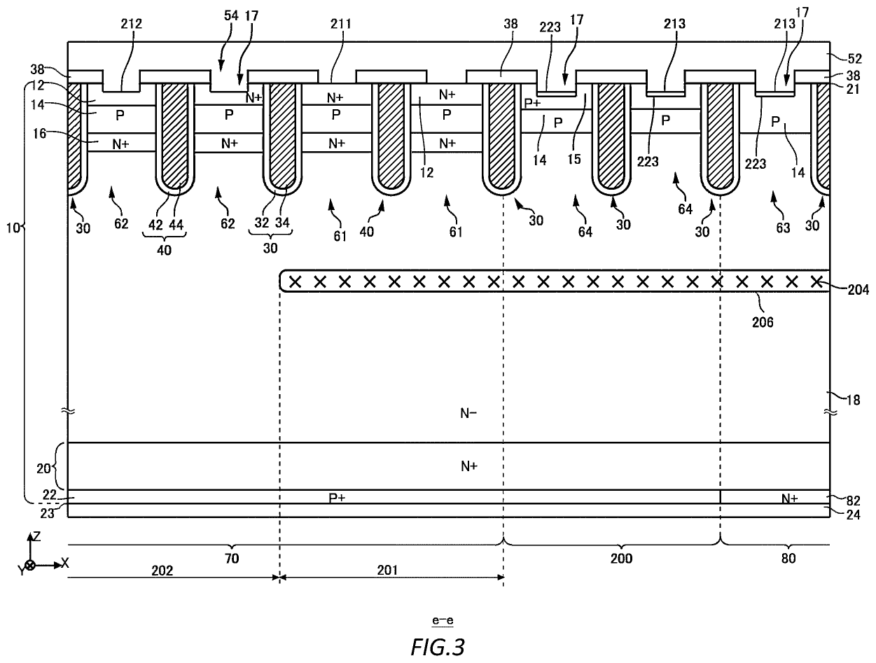

FIG. 3 shows an example of a cross section e-e in FIG. 2. The cross section e-e is the X-Z plane passing through an emitter region 12 and a cathode region 82. A semiconductor device 100 in the present example includes a semiconductor substrate 10, an interlayer dielectric film 38, an emitter electrode 52, and a collector electrode 24 in the cross section.

The interlayer dielectric film 38 is provided on the upper surface of the semiconductor substrate 10. The interlayer dielectric film 38 is a film including at least one layer of a dielectric film such as silicate glass to which an impurity such as boron or phosphorous is added, a thermal oxide film, and other dielectric films. The interlayer dielectric film 38 is provided with a contact hole 54 described with reference to FIG. 2.

The emitter electrode 52 is provided above the interlayer dielectric film 38. The emitter electrode 52 is in contact with an upper surface 21 of the semiconductor substrate 10 through the contact hole 54 of the interlayer dielectric film 38. The collector electrode 24 is provided on a lower surface 23 of the semiconductor substrate 10. The emitter electrode 52 and the collector electrode 24 are formed of a metal material such as aluminum. In the present specification, a direction in which the emitter electrode 52 is connected to the collector electrode 24 (the Z axis direction) is referred to as a depth direction. The emitter electrode 52 may have a barrier metal including titanium at a portion that is in contact with the upper surface 21 of the semiconductor substrate 10. The barrier metal may have a titanium nitride layer, or may have a stacked structure of a titanium nitride layer and a titanium layer. The emitter electrode 52 may have a plug portion formed of tungsten and the like loaded inside the contact hole 54. The plug portion may also be provided in a trench contact portion described below.

The semiconductor substrate 10 includes a drift region 18 of an N type or an N-type. The drift region 18 is provided in each of the transistor portion 70, the diode portion 80, and the boundary region 200.

In the present example, a first mesa portion 61, a second mesa portion 62, a third mesa portion 63, and a fourth mesa portion 64 are included in a plurality of mesa portions 60. The first mesa portion 61 and the second mesa portion 62 are provided in the transistor portion 70, the third mesa portion 63 is provided in the diode portion 80, and the fourth mesa portion 64 is provided in the boundary region 200.

In the first mesa portion 61 and the second mesa portion 62 of the transistor portion 70, an emitter region 12 of an N+ type and a base region 14 of a P type are provided in sequence from an upper surface 21 side of the semiconductor substrate 10. The drift region 18 is provided below the base region 14. The first mesa portion 61 and the second mesa portion 62 may be provided with an accumulation region 16 of an N+ type. The accumulation region 16 is arranged between the base region 14 and the drift region 18.

The emitter region 12 is exposed on the upper surface 21 of the semiconductor substrate 10 and is provided in contact with a gate trench portion 40. The emitter region 12 may be in contact with the trench portions on both sides of the mesa portion 60. The emitter region 12 has a higher doping concentration than that of the drift region 18.

The base region 14 is provided below the emitter region 12. The base region 14 in the present example is provided in contact with the emitter region 12. The base region 14 may be in contact with the trench portions on both sides of the first mesa portion 61 and the second mesa portion 62.

The accumulation region 16 is provided below the base region 14. The accumulation region 16 is a region of the N+ type having a higher doping concentration than that of the drift region 18. That is, the accumulation region 16 has a higher donor concentration than that of the drift region 18. By providing the accumulation region 16 having the high concentration between the drift region 18 and the base region 14, it is possible to improve a carrier injection enhancement effect (IE effect) and reduce an on-voltage. The accumulation region 16 may be provided to cover the entire area of each lower surface of the base region 14 in the first mesa portion 61 and the second mesa portion 62.

The third mesa portion 63 of the diode portion 80 is provided with the base region 14 of the P type that is in contact with the upper surface 21 of the semiconductor substrate 10. In the present specification, the base region 14 of the third mesa portion 63 may be referred to as an anode region. A doping concentration of the base region 14 of the third mesa portion 63 may be the same as or less than a doping concentration of the base region 14 of each of the first mesa portion 61 and the second mesa portion 62. The drift region 18 is provided below the base region 14. In the third mesa portion 63, the accumulation region 16 may be provided below the base region 14.

In the fourth mesa portion 64 of the boundary region 200 in the present example, a contact region 15 of a P+ type is provided to be in contact with the upper surface 21 of the semiconductor substrate 10. The drift region 18 is provided below the contact region 15. The base region 14 may be provided between the contact region 15 and the drift region 18. In the fourth mesa portion 64, the accumulation region 16 may be provided below the base region 14.

In each of the transistor portion 70, the diode portion 80, and the boundary region 200, an N+ type buffer region 20 may be provided below the drift region 18. The doping concentration of the buffer region 20 is higher than the doping concentration of the drift region 18. The buffer region 20 may have a concentration peak having a higher doping concentration than that of the drift region 18. The doping concentration of the concentration peak refers to a doping concentration at the local maximum of the concentration peak. In addition, as the doping concentration of the drift region 18, an average value of doping concentrations in the region where the doping concentration distribution is substantially flat may be used.

The buffer region 20 in this example may have two or more concentration peaks in the depth direction (the Z axis direction) of the semiconductor substrate 10. The concentration peak of the buffer region 20 may be provided at the same depth position as, for example, a chemical concentration peak of hydrogen (a proton) or phosphorous. The buffer region 20 may function as a field stopper layer which prevents a depletion layer expanding from the lower end of the base region 14 from reaching the collector region 22 of a P+ type and the cathode region 82 of the N+ type.

In the transistor portion 70, the collector region 22 of the P+ type is provided below the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

Below the buffer region 20 in the diode portion 80, the cathode region 82 of the N+ type is provided. A donor concentration of the cathode region 82 is higher than a donor concentration of the drift region 18. A donor of the cathode region 82 is, for example, hydrogen or phosphorous. Note that an element serving as a donor and an acceptor in each region is not limited to the example described above.

In the boundary region 200, the collector region 22 of the P+ type is provided below the buffer region 20. The collector region 22 of the boundary region 200 may have a doping concentration the same as that of the collector region 22 of the transistor portion 70. A boundary position between the cathode region 82 and the collector region 22 in an X axis direction may be a boundary position between the diode portion 80 and the boundary region 200 in the X axis direction. In another example, in the boundary region 200, a part of or the entire collector region 22 may be replaced with the cathode region 82. When the cathode region 82 is provided on a lower surface of the boundary region 200, a region in which the contact region 15 and the base region 14 are alternately arranged in a region that is sandwiched between the base regions 14-e may be the diode portion 80, and a region in which the contact region 15 is arranged in the entire region that is sandwiched between the base regions 14-e may be the boundary region 200. When the cathode region 82 is provided on the lower surface of the boundary region 200, the boundary region 200 may be considered as a part of the diode portion 80.

A gate trench portion 40 among the gate trench portions 40 in contact with the emitter region 12, which is arranged to be closest to the diode portion 80 in the X axis direction is a boundary position between the transistor portion 70 and the boundary region 200 (or the diode portion 80) in the X axis direction. A center position of the gate trench portion 40 in the X axis direction may be a boundary position between the transistor portion 70 and the boundary region 200 (or the diode portion 80) in the X axis direction. Of the two trench portions in contact with the emitter region 12 arranged closest to the diode portion 80 in the X axis direction, the trench portion on the diode portion 80 side may be the dummy trench portion 30. The dummy trench portion 30 in this case may be a boundary position between the transistor portion 70 and the boundary region 200 (or the diode portion 80) in the X axis direction.

The boundary region 200 may be provided with the emitter region 12. Note that in that case, the boundary region 200 is not provided with the gate trench portion 40. Moreover, the trench portion at the boundary position between the transistor portion 70 and the boundary region 200 is the dummy trench portion 30. That is, transistor operations do not occur in the boundary region 200. The boundary region 200 may alternatively be provided with the gate trench portion 40. Note that in that case, the boundary region 200 is not provided with the emitter region 12. That is, transistor operations do not occur in the boundary region 200.

The collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided on the upper surface 21 side of the semiconductor substrate 10. Each trench portion is provided from the upper surface 21 of the semiconductor substrate 10 to a region below the base region 14, penetrating the base region 14. In a region where at least any of the emitter region 12, the contact region 15, and the accumulation region 16 is provided, each trench portion also penetrates the doping regions of these. The configuration of the trench portion penetrating the doping region is not limited to the one manufactured in the order of forming the doping region and then forming the trench portion. The configuration of the trench portion penetrating the doping region includes a configuration of the doping region being formed between the trench portions after forming the trench portion.

As described above, the transistor portion 70 is provided with the gate trench portion 40 and a dummy trench portion 30. The diode portion 80 and the boundary region 200 of the present example are provided with the dummy trench portion 30, and are not provided with the gate trench portion 40. Note that the gate trench portion 40 may be arranged or the dummy trench portion 30 may be arranged at the boundary between the boundary region 200 and the transistor portion 70.

Note that the boundary region 200 is a buffer structure for arranging different structures of the transistor portion 70 and the diode portion 80 in parallel. Therefore, the width of the boundary region 200 in the X axis direction may be short. For example, one or several pieces of fourth mesa portion 64 may be provided in the boundary region 200, and the boundary region 200 may not be provided.

In addition, the boundary region 200 may include a plurality of fourth mesa portions 64 in the X axis direction. In this way, an effect of the transistor portion 70 on the characteristics of the diode portion 80, for example, an effect of an operation of the gate trench portion 40 or discharge or implantation of holes in the contact region 15 on a forward voltage or reverse recovery characteristics can be reduced. Herein, the number of the mesa portions refers to the quantity of the mesa portions arranged side by side in the X axis direction.

The gate trench portion 40 includes a gate trench provided in the upper surface 21 of the semiconductor substrate 10, a gate dielectric film 42, and a gate conductive portion 44. The gate dielectric film 42 is provided covering an inner wall of the gate trench. The gate dielectric film 42 may be formed by oxidizing or nitriding a semiconductor on the inner wall of the gate trench. The gate conductive portion 44 is provided farther inward inside the gate trench than the gate dielectric film 42. In other words, the gate dielectric film 42 insulates the gate conductive portion 44 from the semiconductor substrate 10. The gate conductive portion 44 is formed of a conductive material such as polysilicon.

The gate conductive portion 44 may be provided longer than the base region 14 in the depth direction. The gate trench portion 40 in the cross section is covered with the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary surface in contact with the gate trench portion 40. The dummy trench portions 30 may have the same structure as the gate trench portions 40 in the cross section. The dummy trench portion 30 includes a dummy trench provided in the upper surface 21 of the semiconductor substrate 10, a dummy dielectric film 32, and a dummy conductive portion 34. The dummy conductive portion 34 is electrically connected to the emitter electrode 52. The dummy dielectric film 32 is provided covering an inner wall of the dummy trench. The dummy conductive portion 34 is provided inside the dummy trench, and is provided farther inward than the dummy dielectric film 32. The dummy dielectric film 32 insulates the dummy conductive portion 34 from the semiconductor substrate 10. The dummy conductive portion 34 may be formed of the same material as the gate conductive portion 44. For example, the dummy conductive portion 34 is formed of a conductive material such as polysilicon or the like. The dummy conductive portion 34 may have the same length as the gate conductive portion 44 in the depth direction.

The gate trench portion 40 and the dummy trench portion 30 in the present example are covered with the interlayer dielectric film 38 on the upper surface 21 of the semiconductor substrate 10. Note that the bottom portions of the dummy trench portion 30 and the gate trench portion 40 may be formed in a curved-surface shape (a curved shape in the cross section) convexly downward.

The transistor portion 70 has a first contact portion 211 and a second contact portion 212. The first contact portion 211 is a portion in which a first mesa portion 61 and an emitter electrode 52 are in contact with each other. The second contact portion 212 is a portion in which a second mesa portion 62 and an emitter electrode 52 are in contact with each other. The second mesa portion 62 is arranged apart farther from the diode portion 80 than the first mesa portion 61 in the X axis direction. In other words, in the X axis direction, the distance between the diode portion 80 and the second mesa portion 62 is greater than the distance between the diode portion 80 and the first mesa portion 61. Similarly, the second contact portion 212 is arranged farther apart from the diode portion 80 than the first contact portion 211 in the X axis direction. In other words, in the X axis direction, the distance between the diode portion 80 and the second contact portion 212 is greater than the distance between the diode portion 80 and the first contact portion 211.

The semiconductor device 100 may include a lifetime adjustment region 206 including a lifetime killer for adjusting a carrier lifetime. The lifetime adjustment region 206 of the present example is a region where a lifetime of charge carriers is locally small. The charge carriers are electrons or holes. The charge carriers may be simply referred to as carriers. The lifetime adjustment region 206 in the present example is formed by implanting charged particles such as helium ion from the upper surface 21 side of the semiconductor substrate 10. In the present example, a concentration distribution of helium and the like in a depth direction of the semiconductor substrate 10 may have a shape sweeping from the lifetime adjustment region 206 to the upper surface 21 of the semiconductor substrate 10. In other words, a concentration (/cm³) of helium and the like may monotonically decrease from the lifetime adjustment region 206 to the upper surface 21. The concentration of helium and the like in the upper surface 21 may be greater than 0. On the other hand, the concentration of helium and the like may also have a sweeping shape in a direction from the lifetime adjustment region 206 toward the lower surface 23. Note that the concentration of helium and the like falls more steeply in the sweeping shape toward the lower surface 23 than in the shape sweeping toward the upper surface 21. The concentration of helium and the like in the lower surface 23 is lower than the concentration of helium and the like in the upper surface 21. The concentration of helium and the like in the upper surface 21 may be a measurement limitation or less, or may be 0. Note that the lifetime adjustment region 206 may be formed by implanting charged particles such as helium ion from the lower surface 23 side of the semiconductor substrate 10.

By implanting charged particles such as helium ions into the semiconductor substrate 10, the lattice defects 204 such as vacancies are formed in the vicinity of the implantation position. The lattice defects 204 generate recombination centers. The lattice defects 204 may be mainly composed of vacancies such as monatomic vacancies (V) or diatomic vacancies (VV), may be dislocations, may be interstitial atoms, or may be transition metals or the like. For example, atoms adjacent to the vacancies have dangling bonds. In a broad sense, the lattice defects 204 may also include donors and acceptors, but in the present specification, the lattice defects 204 mainly composed of vacancies may be referred to as vacancy-type lattice defects, vacancy-type defects, or simply lattice defects. In the present specification, the lattice defects 204 may be simply referred to as recombination centers or lifetime killers as recombination centers contributing to recombination of carriers. The lifetime killers may be formed by implanting helium ions into the semiconductor substrate 10. A helium chemical concentration may be a density of a lattice defect 204. Note that since the lifetime killer formed by implanting helium ions may be terminated by hydrogen existing in the buffer region 20, the depth position of the density peak of the lifetime killer may not be identical to the depth position of the helium chemical concentration peak. In addition, when implanting hydrogen ions into the semiconductor substrate 10, the lifetime killer may be formed in a passed-through region of hydrogen ions that is more on the implantation surface side than the projected range.

The lattice defect 204 is an example of the lifetime killer. In FIG. 3, the lattice defects 204 at the implantation position of the charged particles are schematically indicated by X marks. In a region where many lattice defects 204 remain, the carriers are captured by the lattice defects 204, and thus the lifetime of the carriers is shortened. By adjusting the lifetime of carriers, characteristics of the diode portion 80 such as a reverse recovery time and a reverse recovery loss can be adjusted. A position at which the carrier lifetime shows a local minimum value in the depth direction of the semiconductor substrate 10 may be set as the depth position of the lifetime adjustment region 206.

The lifetime adjustment region 206 is arranged in the upper surface 21 side of the semiconductor substrate 10. The upper surface 21 side is a region from a center position of the semiconductor substrate 10 in the depth direction to the upper surface 21 of the semiconductor substrate 10. The lifetime adjustment region 206 of the present example is arranged below the lower end of the trench portion.

In addition, if the lifetime adjustment region 206 is formed by irradiating particle beams with high penetrability such as electron beams, a lattice defect is formed substantially uniformly from the upper surface 21 to the lower surface 23 of the semiconductor substrate 10, but the depth position of the lifetime adjustment region 206 may still be considered to be arranged on the upper surface 21 side of the semiconductor substrate 10 in this case.

The lifetime adjustment region 206 may be provided in at least one of the transistor portion 70 or the diode portion 80. If the semiconductor device 100 includes the boundary region 200, the boundary region 200 may be provided with the lifetime adjustment region 206. The lifetime adjustment region 206 may be provided across the entire diode portion 80 in the X axis direction. The lifetime adjustment region 206 may also be provided in the entire boundary region 200.

The lifetime adjustment region 206 of the diode portion 80 may be provided to be extended to a portion of the transistor portion 70 in the X axis direction. The lifetime adjustment region 206 of the diode portion 80 and the lifetime adjustment region 206 of the transistor portion 70 are provided in the same depth position. In the transistor portion 70, a region in which the lifetime adjustment region 206 is provided is an adjustment region 201, and a region in which the lifetime adjustment region 206 is not provided is a non-adjustment region 202. The non-adjustment region 202 is a region in which a carrier lifetime at a depth position that is the same as that of the lifetime adjustment region 206 is longer than a carrier lifetime of the lifetime adjustment region 206 of the diode portion 80. The non-adjustment region 202 may be a region to which charged particle such as helium ion for forming a lifetime killer such as the lattice defect 204 is not implanted. A chemical concentration (/cm³) of helium and the like in the non-adjustment region 202 may be the same as a chemical concentration of the charged particle at the center of the Z axis direction of the drift region 18.

The lifetime adjustment region 206 may be provided below at least a part of the first mesa portion 61 and the first contact portion 211. The lifetime adjustment region 206 may be provided below a part of the first mesa portion 61 and the first contact portion 211, or the lifetime adjustment region 206 may be provided below the entire first mesa portion 61 and the first contact portion 211. The lifetime adjustment region 206 may be provided below at least a part of the second mesa portion 62 and the second contact portion 212. The lifetime adjustment region 206 may be provided below a part of the second mesa portion 62 and the second contact portion 212, or the lifetime adjustment region 206 may be provided below the entire second mesa portion 62 and the second contact portion 212.

The lifetime adjustment region 206 may be provided at least one of: below the first mesa portion 61; or in the diode portion 80. The lifetime adjustment region 206 may be provided in at least any of: below the first mesa portion 61; below the second mesa portion 62; or in the diode portion 80. In the example of FIG. 3, the lifetime adjustment region 206 is provided both: below the first mesa portion 61; and in the diode portion 80.

The diode portion 80 has a third contact portion 213 in which the third mesa portion 63 and the emitter electrode 52 are in contact with each other. The third contact portion 213 may be provided for a part of the third mesa portion 63, or the third contact portion 213 may be provided for the entire third mesa portion 63. The boundary region 200 has a third contact portion 213 in which the fourth mesa portion 64 and the emitter electrode 52 are in contact with each other. In other words, the boundary region 200 has the third contact portion 213 with a structure that is the same as that of the diode portion 80. The third contact portion 213 may be provided for a part of the fourth mesa portion 64, or the third contact portion 213 may be provided for the entire fourth mesa portion 64.

In the present example, each contact portion refers to a boundary surface at which the emitter electrode 52 and the semiconductor substrate 10 are in contact with each other. The contact portion may include a surface of the emitter electrode 52 and a surface of the semiconductor substrate 10. If a metal silicide layer is formed on the boundary surface between the emitter electrode 52 and the semiconductor substrate 10, the metal silicide layer may be included in the emitter electrode 52 (metal electrode). In other words, a boundary surface between the metal silicide layer and the semiconductor substrate 10 may be the contact portion.

In at least a part of the mesa portion 60, a trench contact portion 17 may be provided. The trench contact portion 17 is a portion in which a metal electrode such as the emitter electrode 52 is provided inside the semiconductor substrate 10. The trench contact portion 17 can be formed by forming a groove in the upper surface 21 of the semiconductor substrate 10 that is exposed via the contact hole 54 and loading the metal electrode inside the groove. In the mesa portion 60 in which the trench contact portion 17 is provided, a region in which the mesa portion 60 and the metal electrode such as the emitter electrode 52 are in contact with each other in the trench contact portion 17 corresponds to the contact portion. In the example of FIG. 3, the trench contact portion 17 is provided in each of the second mesa portion 62, the third mesa portion 63, and the fourth mesa portion 64.

In at least a part of the mesa portion 60, a plug region may be provided in a region in contact with a lower end of the contact portion. The plug region is a region of a P++ type having a doping concentration higher than that of the contact region 15. In the example of FIG. 3, a third plug region 223 is provided to be in contact with the third contact portion 213.

The first contact portion 211 of the first mesa portion 61 indicated in FIG. 3 may be provided at a depth shallower than a lower end of the emitter region 12. Note that the first plug region 221 is not provided at a lower end of the first contact portion 211. In another example, the first contact portion 211 may be provided at a depth reaching the base region 14, or the first plug region 221 may be provided to be in contact with the lower end of the first contact portion 211.

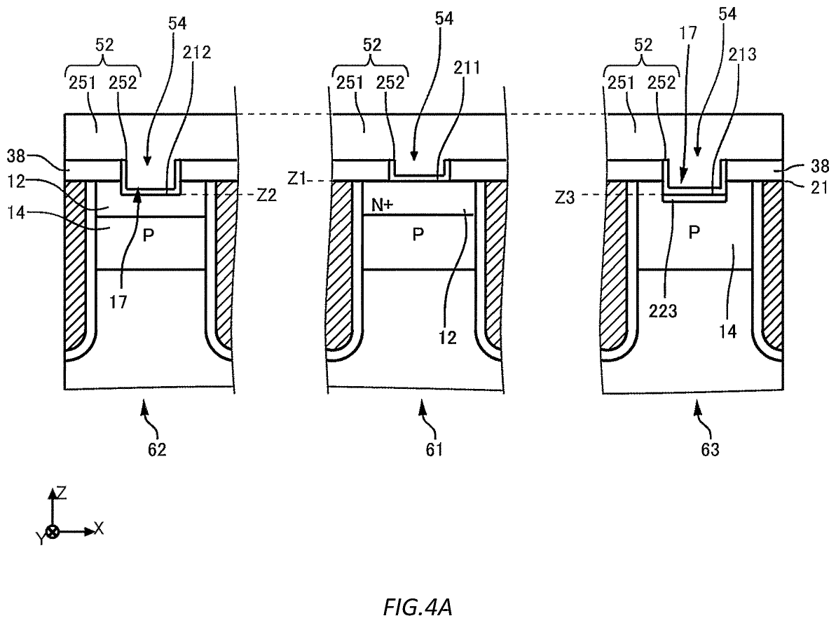

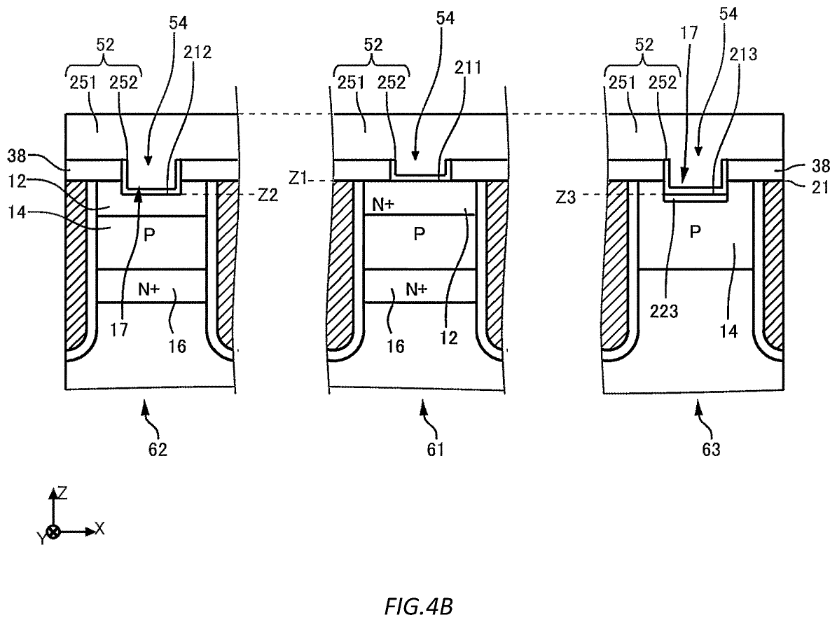

FIG. 4A is an enlarged view of a vicinity of a first mesa portion 61, a second mesa portion 62, and a third mesa portion 63. In FIG. 4A, each of the first mesa portion 61, the second mesa portion 62, and the third mesa portion 63 is indicated one by one, and regions between the respective mesa portions are omitted.

The emitter electrode 52 (metal electrode) of the present example includes a barrier metal portion 252 and an upper portion 251. The barrier metal portion 252 is provided above the upper surface 21 of the semiconductor substrate 10. The barrier metal portion 252 is at least provided in a contact hole 54 or a bottom surface of the trench contact portion 17. The barrier metal portion 252 may be provided at a lower end of each contact portion. The barrier metal portion 252 may be in contact with the semiconductor substrate 10. The barrier metal portion 252 may be provided on the contact hole 54 and a side surface of the trench contact portion 17. The barrier metal portion 252 may also be provided or may not be provided on the upper surface of the interlayer dielectric film 38.

The barrier metal portion 252 is formed of a material with a higher occlusion of hydrogen than that of the upper portion 251. In this way, entering of hydrogen ion into the semiconductor substrate 10 is reduced. The barrier metal portion 252 of the present example includes titanium. The barrier metal portion 252 may include a titanium nitride layer. The barrier metal portion 252 may be a laminated film of a titanium layer and a titanium nitride layer.

The upper portion 251 is provided above the barrier metal portion 252. The upper portion 251 is also provided above the interlayer dielectric film 38. The upper portion 251 is formed of a material that is different from that of the barrier metal portion 252. The upper portion 251 of the present example does not include titanium. As an example, the upper portion 251 includes aluminum. The upper portion 251 may be an alloy of aluminum and silicon. The upper portion 251 inside the contact hole 54 or the trench contact portion 17 may include a plug portion formed of tungsten and the like, and the plug portion may be provided to an area above the interlayer dielectric film 38.

A depth position at the lower end of the first contact portion 211 is Z1, a depth position at the lower end of the second contact portion 212 is Z2, and a depth position at the lower end of the third contact portion 213 is Z3. The lower end of each contact portion refers to a portion that is arranged at the lowest position in a boundary surface in which the metal electrode and the semiconductor substrate 10 are in contact with each other. The depth position Z1 is arranged above the depth position Z2. In other words, the depth position Z2 is farther apart from the upper surface 21 of the semiconductor substrate 10 than the depth position Z1. In the example of FIG. 4A, the depth position Z2 is a position below the upper surface 21 of the semiconductor substrate 10, and the depth position Z1 is a depth position that is the same as that of the upper surface 21 of the semiconductor substrate 10. In another example, the depth position Z1 may be a position between the depth position Z2 and the upper surface 21 of the semiconductor substrate 10. In this case, with reference to the upper surface 21 of the semiconductor substrate 10, the depth position Z1 may be a depth of half or less of the depth position Z2, or may be a depth of ¼ or less.

By forming the first contact portion 211 at a position that is shallower than that of the second contact portion 212, the volume of the contact region 15 of the first mesa portion 61 that is etched can be less than the volume of the contact region 15 of the second mesa portion 62 that is etched. In other words, the contact region 15 of the first mesa portion 61 can remain to be greater than the contact region 15 of the second mesa portion 62. Thus, a hole implantation amount from the second mesa portion 62 can be increased. The second mesa portion 62 is arranged in a vicinity of the diode portion 80. Thus, by increasing the hole implantation amount from the second mesa portion 62, holes flowing into the diode portion 80 can be increased, to reduce a forward voltage of the diode portion 80.

Among the mesa portions 60 of the transistor portions 70, one or more mesa portion 60 that are the closest to the diode portion 80 are the first mesa portions 61, and the remaining mesa portions 60 may be the second mesa portion 62. In the transistor portion 70, two or more mesa portions 60 in contact with the diode portion 80 may be the first mesa portion 61. In the transistor portion 70, the number of the first mesa portions 61 may be less than or greater than the number of the second mesa portions 62, or may be the same.

In the adjustment region 201, a lifetime adjustment region 206 (refer to FIG. 3) is formed by irradiating charged particles from the upper surface 21. On the other hand, a level is formed on the gate dielectric film 42 of the adjustment region 201 by irradiating the charged particles, and a threshold voltage (on-voltage, off-voltage) in the adjustment region 201 may decrease to be lower than a threshold voltage in the non-adjustment region 202. Because a timing of turn-off is delayed when the threshold voltage decreases, a turn-off of the adjustment region 201 is delayed to be later than that of the non-adjustment region 202, and therefore a current crowding occurs in the adjustment region 201, thereby a withstand capability may decrease.

In the semiconductor device 100 of the present example, the depth position Z2 of the second contact portion 212 is at a position deeper than that of the depth position Z1 of the first contact portion 211. In this way, the volume of the barrier metal portion 252 in one piece of the second mesa portion 62 can easily be greater than the volume of the barrier metal portion 252 in one piece of the first mesa portion 61. Note that the volume of the barrier metal portion 252 in one piece of the mesa portion refers to the volume of the barrier metal portion 252 provided inside the trench contact portion 17 above the mesa portion and the contact hole 54.

A manufacturing process of the semiconductor device 100 includes a process of annealing the semiconductor substrate 10 in a hydrogen atmosphere, for example. By the process, oxygen enters inside the semiconductor substrate 10 and the dielectric film, and terminates a defect. In this way, the decrease of the threshold voltage is reduced.

Because the barrier metal portion 252 occludes hydrogen, the entering of hydrogen into the first mesa portion 61 in which many barrier metal portions 252 are formed is reduced compared to the second mesa portion 62. Thus, the threshold voltage in the first mesa portion 61 decreases compared to the second mesa portion 62, and the threshold voltage in the first mesa portion 61 can be relatively increased. In this way, the decrease of the threshold voltage in the first mesa portion 61 due to the formation of the lifetime adjustment region 206 can be compensated. The volume of the barrier metal portion 252 in one piece of the second mesa portion 62 may be 1.1 times or more, 1.2 times or more, or 1.5 times or more of the volume of the barrier metal portion 252 in one piece of the first mesa portion 61.

If the adjustment region 201 and the non-adjustment region 202 are provided in the transistor portion 70, at least one piece of the first mesa portion 61 and the first contact portion 211 may be arranged in the adjustment region 201, and at least one piece of the second mesa portion 62 and the second contact portion 212 may be arranged in the non-adjustment region 202.

All of the mesa portions 60 in the adjustment region 201 may be the first mesa portion 61. All of the mesa portions 60 in the non-adjustment region 202 may be the second mesa portion 62.

In the non-adjustment region 202, the decrease of the threshold voltage due to the irradiation of the charged particles is less. By forming the second contact portion 212 of the second mesa portion 62 of the non-adjustment region 202 to be deep, the extraction of the hole can be facilitated, to ensure the withstand capability. In the adjustment region 201 arranged near the diode portion 80, a latch-up is hardly generated. Thus, by forming the first contact portion 211 of the first mesa portion 61 of the adjustment region 201 at a shallow position, the characteristics of the semiconductor device 100 can be adjusted. In addition, the withstand capability is improved because the lifetime adjustment region 206 is provided in the adjustment region 201.

The lower end of the first contact portion 211 of the present example is arranged above the third contact portion 213. A depth position Z3 of the third contact portion 213 may be the same as the depth position Z2 of the second contact portion 212, or may be arranged between the depth position Z2 and the depth position Z1. In addition, the depth position Z3 of the third contact portion 213 may be the same as the depth position Z1 of the first contact portion 211.

The third mesa portion 63 may have a third plug region 223 of a P++ type provided to be in contact with the lower end of the third contact portion 213 and having a doping concentration higher than that of a base region 14 (anode region). The third plug region 223 may have a doping concentration higher than that of the contact region 15. The base region 14 (anode region) of the third mesa portion 63 may have a doping concentration lower than that of a base region 14 of the transistor portion 70. In this case, the implantation of holes from the third mesa portion 63 to the drift region 18 can be reduced.

FIG. 4B is an enlarged view of a vicinity of the first mesa portion 61, the second mesa portion 62, and the third mesa portion 63. In FIG. 4B, each of the first mesa portion 61, the second mesa portion 62, and the third mesa portion 63 is indicated one by one, and regions between the respective mesa portions are omitted.

FIG. 4B is different from FIG. 4A in that FIG. 4B includes an accumulation region 16 below the base region 14 provided in the first mesa portion 61 and the second mesa portion 62. In the present example, an on-voltage can be reduced by increasing a carrier injection enhancement effect (IE effect) by including the accumulation region 16. An effect similar to that of FIG. 4A can be obtained, even if the accumulation region 16 is included below the base region 14 provided in the first mesa portion 61 and the second mesa portion 62 as the present example.

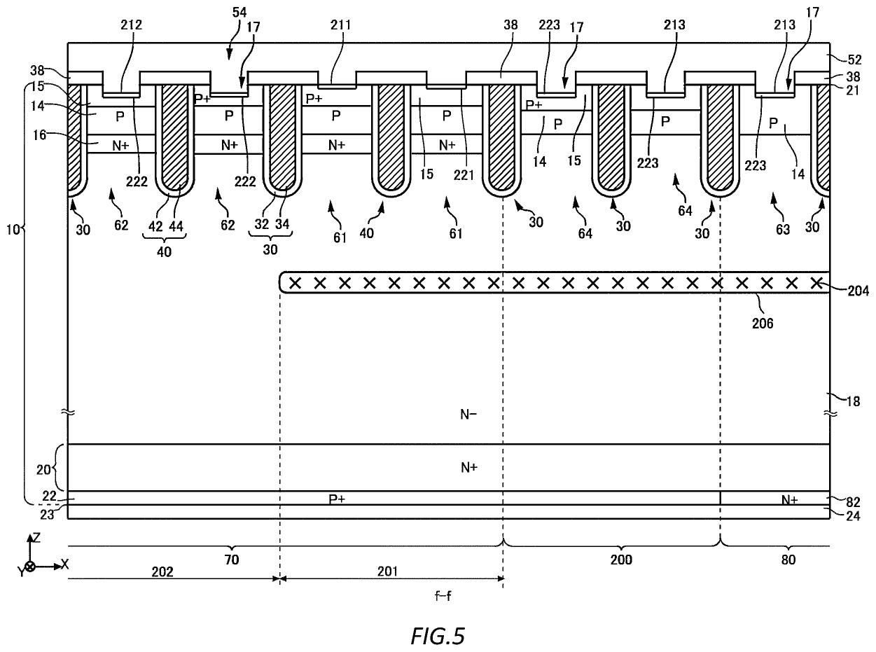

FIG. 5 shows an example of a cross section f-f in FIG. 2. The cross section f-f is an X-Z plane passing through a contact region 15 and a cathode region 82. In the cross section f-f, the contact region 15 is arranged instead of the emitter region 12 in the cross section e-e shown in FIG. 3. Other structures are similar to those of the cross section e-e. Also in the cross section f-f, a structure of the first contact portion 211, the second contact portion 212, and the third contact portion 213 is similar to that of the cross section e-e.

The first mesa portion 61 of the present example has a first plug region 221 of a P++ type provided to be in contact with a lower end of the first contact portion 211 and having a doping concentration higher than that of the contact region 15. At least a part of the first plug region 221 is provided to overlap the contact region 15 in a top view. In other words, in any X-Z cross section passing through the contact region 15, the first plug region 221 is provided. The first plug region 221 may be provided in an X-Z cross section passing through the center of the contact region 15 in the Y axis direction. A part of the first plug region 221 may overlap the emitter region 12 in a top view. In an end region of the emitter region 12 that is in contact with the contact region 15, the first plug region 221 may be provided. In any X-Z cross section passing through the emitter region 12, the first plug region 221 may not be provided. For example, in an X-Z cross section passing through the center of the emitter region 12 in the Y axis direction, the first plug region 221 is not provided. The entire first plug region 221 may be provided to overlap the contact region 15. In this case, the first plug region 221 does not overlap the emitter region 12 in a top view.

The second mesa portion 62 of the present example has a second plug region 222 of a P++ type provided to be in contact with a lower end of the second contact portion 212 and having a doping concentration higher than that of the contact region 15. At least a part of the second plug region 222 is provided to overlap the contact region 15 in a top view. In other words, in any X-Z cross section passing through the contact region 15, the second plug region 222 is provided. The second plug region 222 may be provided in an X-Z cross section passing through the center of the contact region 15 in the Y axis direction. A part of the second plug region 222 may overlap the emitter region 12 in a top view. In an end region of the emitter region 12 that is in contact with the contact region 15, the second plug region 222 may be provided. In any X-Z cross section passing through the emitter region 12, the second plug region 222 may not be provided. For example, in an X-Z cross section passing through the center of the emitter region 12 in the Y axis direction, the second plug region 222 is not provided. The entire second plug region 222 may be provided to overlap the contact region 15. In this case, the second plug region 222 does not overlap the emitter region 12 in a top view. By providing each plug region, the holes can be easily extracted in each mesa portion. For this reason, it is possible to reduce reduction in withstand capability.

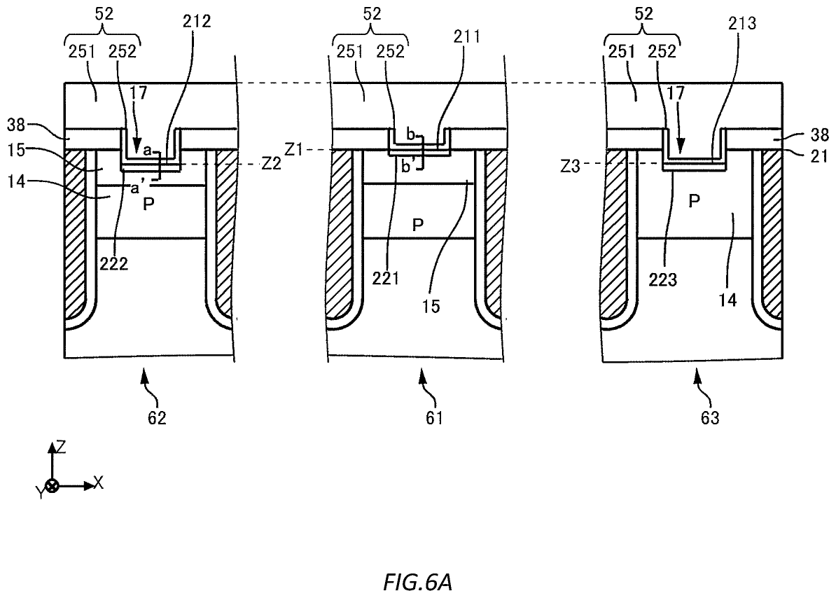

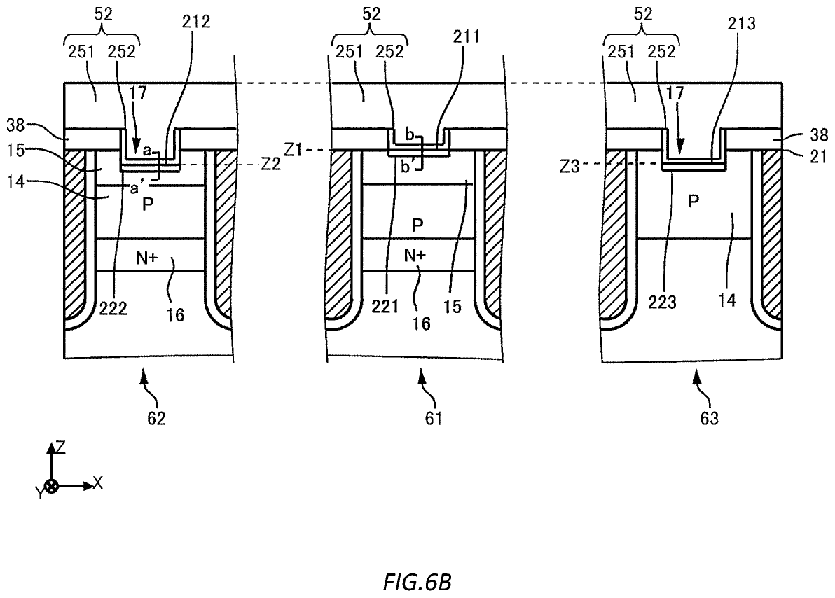

FIG. 6A is an enlarged view of a vicinity of the first mesa portion 61, the second mesa portion 62, and the third mesa portion 63 shown in FIG. 5. In FIG. 6A, each of the first mesa portion 61, the second mesa portion 62, and the third mesa portion 63 is indicated one by one, and regions between the respective mesa portions are omitted. The structure of the third mesa portion 63 is similar to that of the third mesa portion 63 shown in FIG. 4A.

Compared to the structure shown in FIG. 4A, the first mesa portion 61 has a contact region 15 instead of the emitter region 12, and a first plug region 221 in contact with the lower end of the first contact portion 211. Other structures are similar to those of the example shown in FIG. 4A. Compared to the structure shown in FIG. 4A, the second mesa portion 62 has a contact region 15 instead of the emitter region 12, and a second plug region 222 in contact with the lower end of the second contact portion 212. Other structures are similar to those of the example shown in FIG. 4A.

The second plug region 222 may be provided at a position lower than the first plug region 221. Each plug region is a region of a P++ type with a high concentration. The first plug region 221 and the second plug region 222 may be formed by implanting impurities with a different dose amount (cm²). The first plug region 221 and the second plug region 222 may be formed by implanting impurities with a same dose amount. In this case, the semiconductor device can be manufactured by a simple process.

FIG. 6B is an enlarged view of a vicinity of the first mesa portion 61, the second mesa portion 62, and the third mesa portion 63 shown in FIG. 5. In FIG. 6B, each of the first mesa portion 61, the second mesa portion 62, and the third mesa portion 63 is indicated one by one, and regions between the respective mesa portions are omitted. The structure of the third mesa portion 63 is similar to that of the third mesa portion 63 shown in FIG. 4B.

FIG. 6B is different from FIG. 6A in that FIG. 6B includes an accumulation region 16 below the base region 14 provided in the first mesa portion 61 and the second mesa portion 62. In the present example, an on-voltage can be reduced by increasing a carrier injection enhancement effect (IE effect) by including the accumulation region 16. An effect similar to that of FIG. 6A can be obtained, even if the accumulation region 16 is included below the base region 14 provided in the first mesa portion 61 and the second mesa portion 62 as the present example.

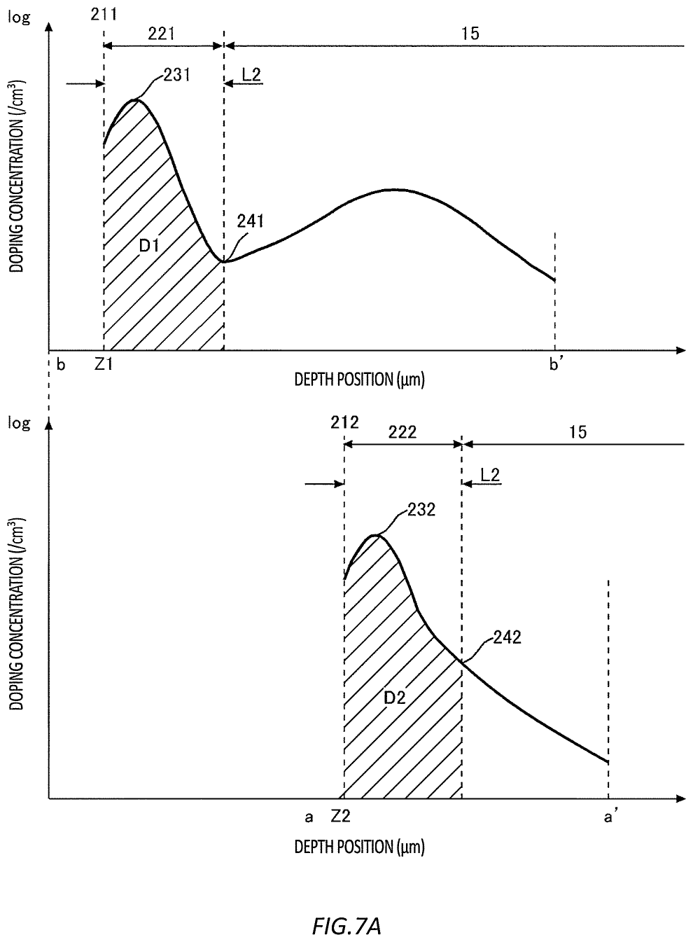

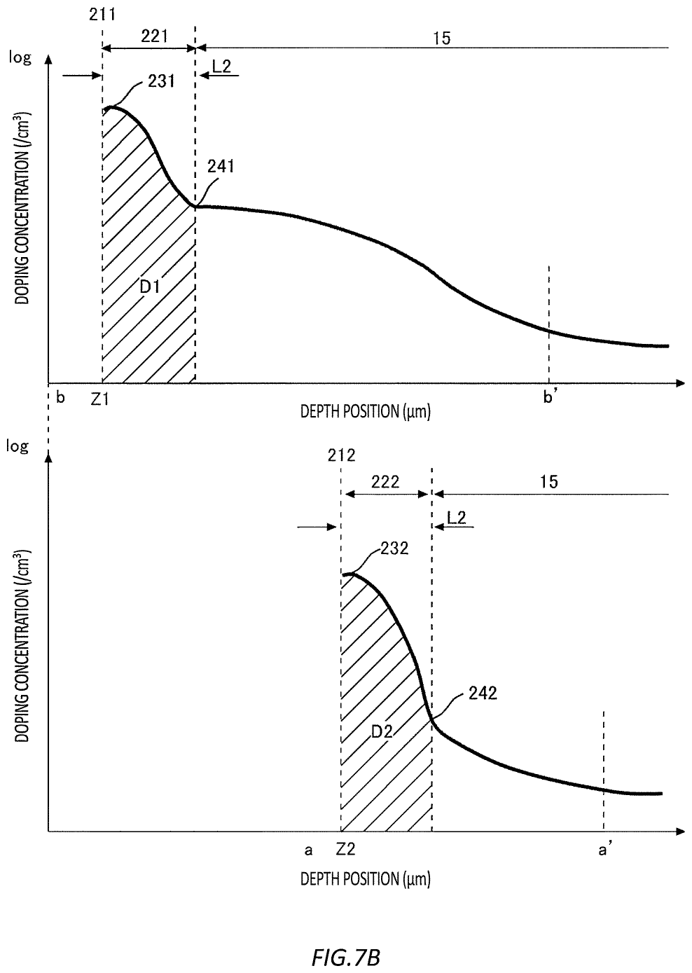

FIG. 7A shows an example of a doping concentration distribution in the line a-a and the line b-b in FIG. 6A. The line a-a is a line that is parallel to the Z axis, which passes through the second plug region 222. The line b-b is a line that is parallel to the Z axis, which passes through the first plug region 221. Each of the first plug region 221 and the second plug region 222 has a first peak 231 and a second peak 232 of doping concentration. The first plug region 221 has a joint portion 241 of doping concentrations at a boundary of the contact region 15. The second plug region 222 of the present example does not have a valley portion of doping concentrations at the boundary of the contact region 15, but may have a joint portion that is a valley portion.

A dose amount of the second plug region 222 is indicated as D2, and a dose amount of the first plug region 221 is indicated as D1. The dose amount D1 may take a value obtained by integrating, in a depth direction, a doping concentration from the lower end position Z1 of the first contact portion 211 to the joint portion 241 of the doping concentrations. Similarly, the dose amount D2 may take a value obtained by integrating, in a depth direction, a doping concentration from the lower end position Z2 of the second contact portion 212 to a joint portion 242 of doping concentrations. If the valley portion of the doping concentrations does not exist at the boundary between the second plug region 222 and the contact region 15, a value obtained by integrating a doping concentration from the depth position Z2 over a predetermined depth distance L2 may be the dose amount D2. The distance L2 is a distance in the depth direction from the depth position Z1 in the first plug region 221 to the joint portion 241, for example. In other words, in the first plug region 221 and the second plug region 222, a value obtained by integrating doping concentration over the same distance L2 may be used as a dose amount of each plug region. In another example, a value obtained by integrating a doping concentration from a lower end position (Z1 or Z2) of each contact portion to a peak of the doping concentration (the first peak 231 or the second peak 232) may be used as an indicator indicating each dose amount. In addition, the doping concentration at the peak of the doping concentration (the first peak 231 or the second peak 232) may be used as an indicator indicating each dose amount.

As described above, the dose amount D1 and the dose amount D2 may be the same. The same dose amount may allow an error of +20%, may allow an error of +10%, or may allow an error of +5%.

FIG. 7B shows an example of a doping concentration distribution in the line a-a and the line b-b in FIG. 6B. The line a-a is a line that is parallel to the Z axis, which passes through the second plug region 222. The line b-b is a line that is parallel to the Z axis, which passes through the first plug region 221. Each of the first plug region 221 and the second plug region 222 has a first peak 231 and a second peak 232 of doping concentration.

A dose amount of the second plug region 222 is indicated as D2, and a dose amount of the first plug region 221 is indicated as D1. The dose amount D1 may take a value obtained by integrating, in a depth direction, a doping concentration from the lower end position Z1 of the first contact portion 211 to the joint portion 241 of the doping concentrations. Similarly, the dose amount D2 may take a value obtained by integrating, in a depth direction, a doping concentration from the lower end position Z2 of the second contact portion 212 to a joint portion 242 of doping concentrations. A value obtained by integrating a doping concentration from the depth position Z2 over a predetermined depth distance L2 may be the dose amount D2. The distance L2 is a distance in the depth direction from the depth position Z1 in the first plug region 221 to the joint portion 241, for example. In other words, in the first plug region 221 and the second plug region 222, a value obtained by integrating doping concentration over the same distance L2 may be used as a dose amount of each plug region. In another example, a value obtained by integrating a doping concentration from a lower end position (Z1 or Z2) of each contact portion to a peak of the doping concentration (the first peak 231 or the second peak 232) may be used as an indicator indicating each dose amount. In addition, the doping concentration at the peak of the doping concentration (the first peak 231 or the second peak 232) may be used as an indicator indicating each dose amount.

The lower end of the first contact portion 211 is in contact with a region in which a doping concentration of the contact region 15 is higher than that of the lower end of the second contact portion 212 which is a bottom portion of the trench contact portion 17. Accordingly, compared to a case in which the lower end position Z1 of the first contact portion 211 is at the same depth as that of the lower end position Z2 of the second contact portion 212, hole injection from the first mesa portion 61 is greater, and the forward voltage is less. Therefore, the forward voltage can be reduced by providing the trench contact portion 17 to the first mesa portion 61 of the transistor portion 70.

As described above, the dose amount D1 and the dose amount D2 may be the same. The same dose amount may allow an error of ±20%, may allow an error of ±10%, or may allow an error of ±5%. The first plug region 221 and the second plug region 222 are formed by exposing the first contact portion 211 and the second contact portion 212 and performing ion implantation, but a concentration difference between the doping concentrations of the contact regions 15 of the first contact portion 211 and the second contact portion 212 is sufficiently smaller than the doping concentration of the first peak 231 and the second peak 232 to be formed.

Each of FIG. 7A and FIG. 7B shows an example of a doping concentration distribution in the line a-a and the line b-b in each of FIG. 6A and FIG. 6B, but the doping concentration distribution is not limited to this distribution. For example, the doping concentration distribution in the line a-a and the line b-b of FIG. 6A may be the doping concentration distribution in FIG. 7B, or may be another doping concentration distribution. In addition, the doping concentration distribution in the line a-a and the line b-b of FIG. 6B may be the doping concentration distribution in FIG. 7A, or may be another doping concentration distribution.

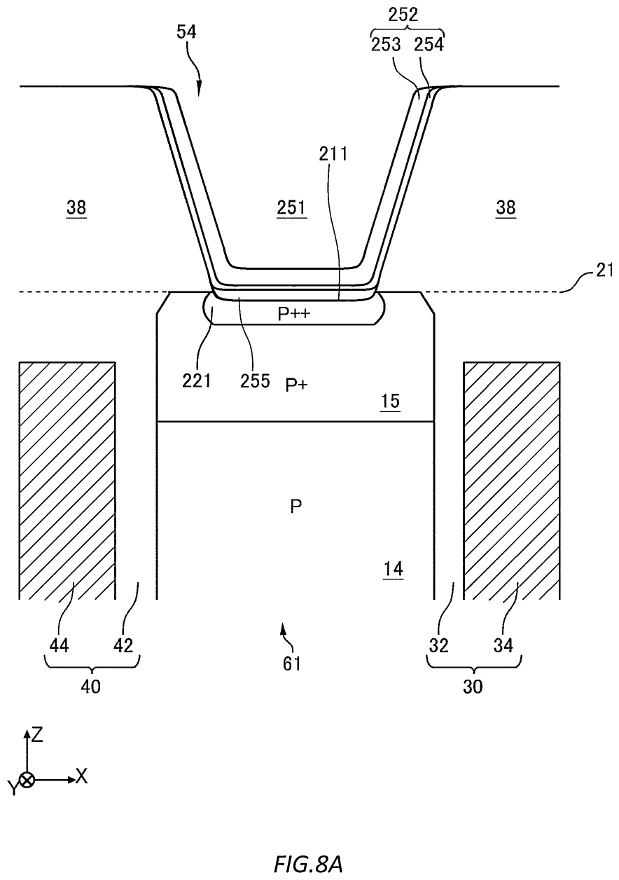

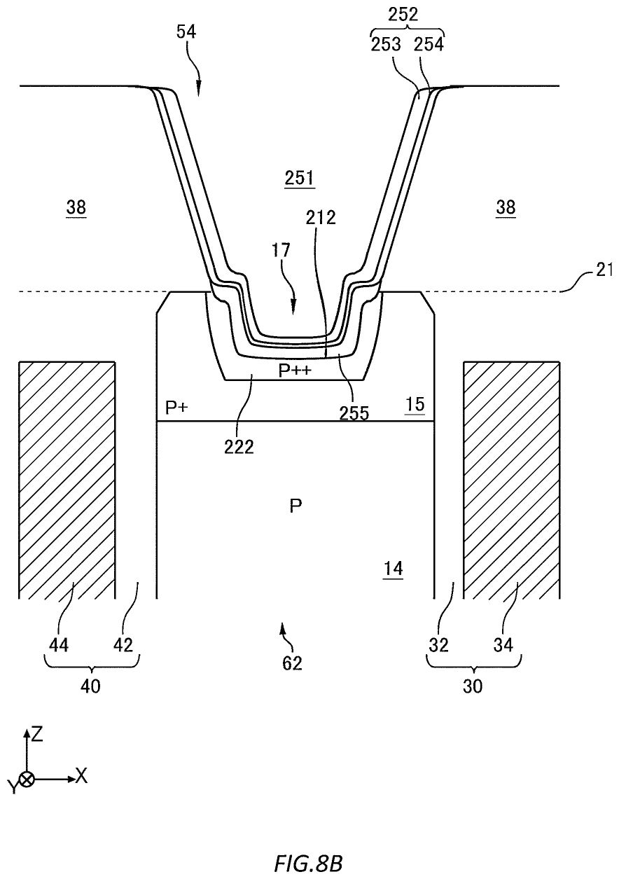

FIG. 8A is an enlarged view that is in the vicinity of the first contact portion 211. The barrier metal portion 252 of the present example has a first layer 253 and a second layer 254. The first layer 253 is a titanium layer or a titanium nitride layer provided between the upper portion 251 and the semiconductor substrate 10. The second layer 254 is a titanium nitride layer provided between the first layer 253 and the semiconductor substrate 10.

The barrier metal portion 252 of the first mesa portion 61 is provided inside the contact hole 54. The barrier metal portion 252 may be in contact with the upper surface 21 of the semiconductor substrate 10. The barrier metal portion 252 may further have a silicide layer 255. The silicide layer 255 is formed at a position in contact with the semiconductor substrate 10. The silicide layer 255 is a layer in which a part of the second layer 254 is silicided. At a position in contact with the upper surface 21 of the semiconductor substrate 10 of the barrier metal portion 252, not the entire area of the second layer 254 may exist being changed into the silicide layer 255.

FIG. 8B is an enlarged view that is in the vicinity of the second contact portion 212. Similar to the example of FIG. 8A, the barrier metal portion 252 has a first layer 253 and a second layer 254. In addition, the barrier metal portion 252 may have a silicide layer 255.

The barrier metal portion 252 of the second mesa portion 62 is provided inside the contact hole 54 and the trench contact portion 17. Thus, the volume is greater than that of the barrier metal portion 252 of the first mesa portion 61. The thickness of the barrier metal portion 252 provided on a sidewall of the contact hole 54 of the first mesa portion 61 may be the same as the thickness of the barrier metal portion 252 provided on a sidewall of the contact hole 54 of the second mesa portion 62. The barrier metal portion 252 of the first mesa portion 61 and the barrier metal portion 252 of the second mesa portion 62 may be formed by the same process.

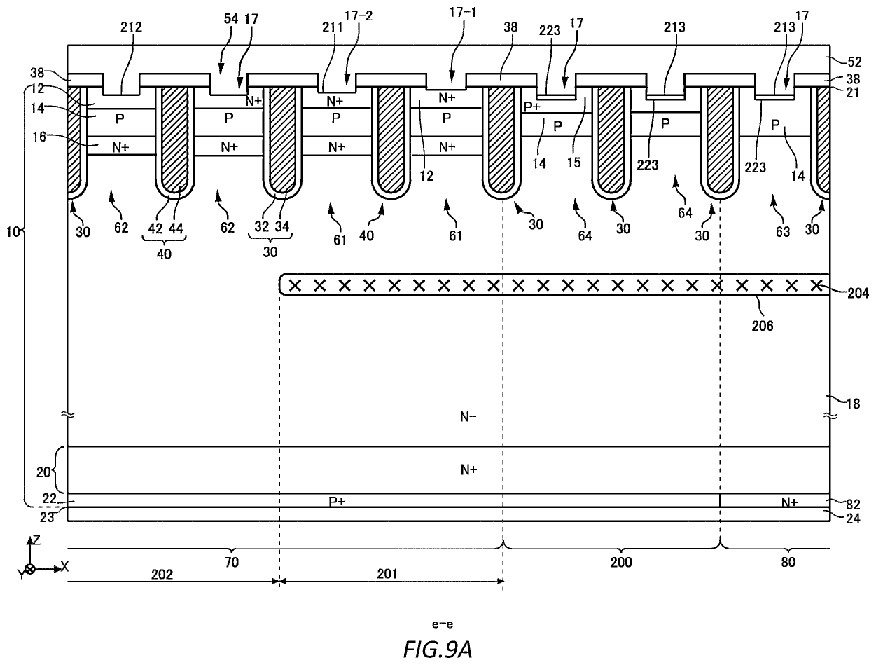

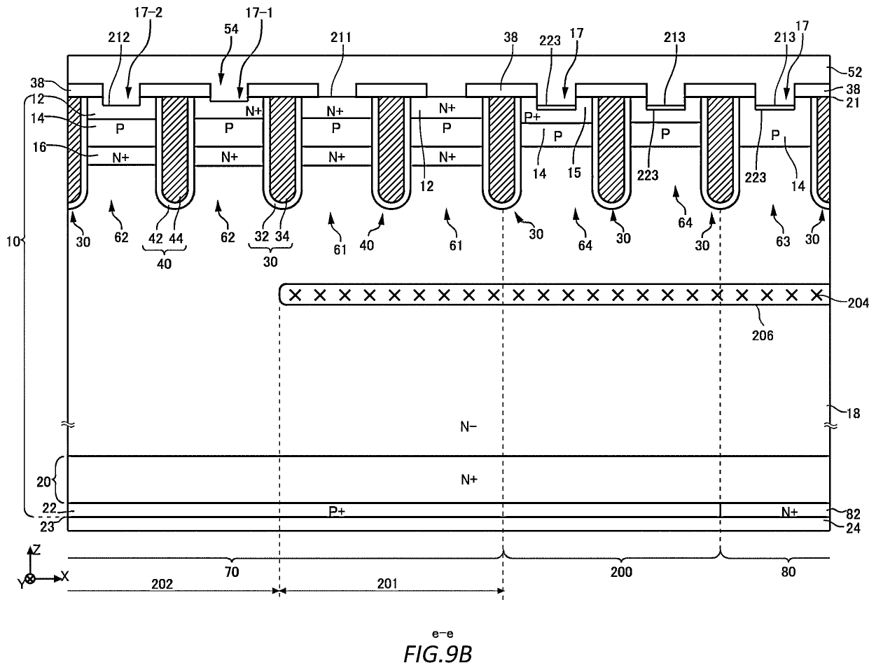

FIG. 9A shows another example of the cross section e-e. In the present example, the adjustment region 201 includes two or more first mesa portions 61 arranged side by side in the X axis direction. The semiconductor device 100 in the present example has a structure of the trench contact portion 17 of the first mesa portion 61 that is different from that of another example described in the present specification. Structures other than the trench contact portion 17 of the first mesa portion 61 are similar to those of any aspect described in the present specification. In the present example, at least one piece of the trench contact portion 17-2 of the first

mesa portion 61 is provided to a position deeper than that of a trench contact portion 17-1 of a first mesa portion 61 arranged closer to the diode portion 80 than the at least one first mesa portion 61. Each trench contact portion 17 of the first mesa portion 61 may be formed to a deeper position as the trench contact portion 17 is apart farther from the diode portion 80. Note that the adjustment region 201 may include two or more trench contact portions 17 arranged adjacent to each other in the X axis direction and having the same depth. By such a structure, the volume of the barrier metal portion 252 in the first mesa portion 61 can be gradually changed.

In another example, the depth of each trench contact portion 17 may be adjusted according to the density of the lattice defect 204 in the lifetime adjustment region 206 below. As an example, as the density of the lattice defect 204 arranged below is thinner, the trench contact portion 17 may be formed deeper. As the trench contact portion 17 is formed deeper, the volume of the barrier metal portion 252 is greater. In this way, the fluctuation of the threshold voltage can be easily compensated. As an example, when the density of the lattice defect 204 becomes thinner as the lattice defect 204 is farther apart from the diode portion 80, the trench contact portion 17 may be formed deeper as the trench contact portion 17 is farther apart from the diode portion 80.

FIG. 9B shows another example of the cross section e-e. In the present example, the non-adjustment region 202 includes two or more second mesa portions 62 arranged side by side in the X axis direction. The semiconductor device 100 in the present example has a structure of the trench contact portion 17 of the second mesa portion 62 that is different from that of another example described in the present specification. Structures other than the trench contact portion 17 of the second mesa portion 62 are similar to those of any aspect described in the present specification.

In the present example, at least one piece of the trench contact portion 17-2 of the second mesa portion 62 is provided to a position deeper than that of a trench contact portion 17-1 of a second mesa portion 62 arranged closer to the diode portion 80 than the at least one second mesa portion 62. Each trench contact portion 17 of second mesa portion 62 may be formed to a deeper position as the trench contact portion 17 is apart farther from the diode portion 80. Note that the non-adjustment region 202 may include two or more trench contact portions 17 arranged adjacent to each other in the X axis direction and having the same depth. By such a structure, the volume of the barrier metal portion 252 in the second mesa portion 62 can be gradually changed.

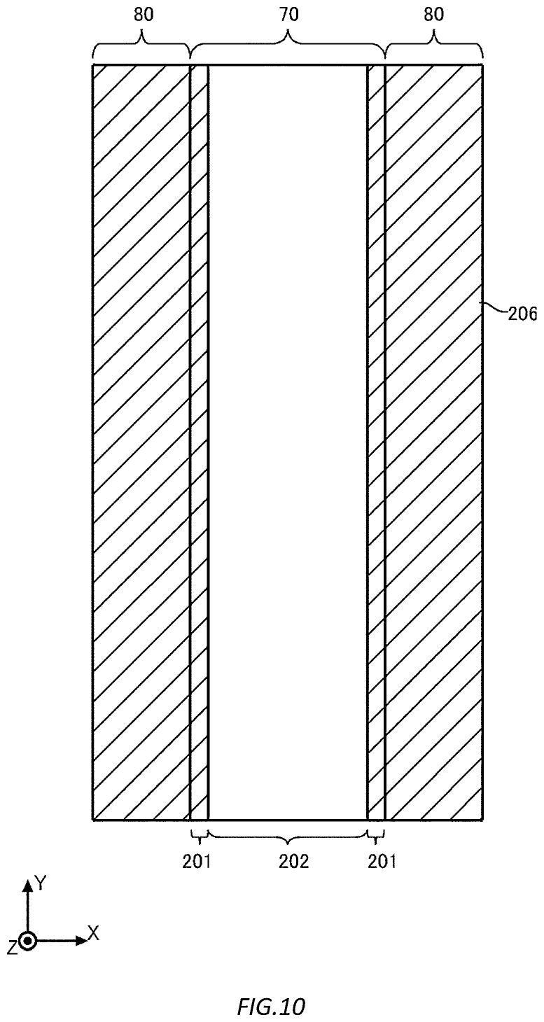

FIG. 10 shows an exemplary arrangement of an adjustment region 201 and a non-adjustment region 202 in a top view. In FIG. 10, two pieces of diode portion 80 and one piece of the transistor portion 70 are shown, and other regions are omitted. Also in FIG. 10, a region in which the lifetime adjustment region 206 is provided is hatched with diagonal lines.

The adjustment region 201 may be provided across the entire diode portion 80 in the X axis direction. In addition, the adjustment region 201 is also provided in a region that is in contact with the diode portion 80 (or the boundary region 200) in the transistor portion 70. The area of the non-adjustment region 202 in the transistor portion 70 may be greater than the area of the adjustment region 201. In the non-adjustment region 202, the first contact portion 211 is arranged above the second contact portion 212. In this way, the volume of the barrier metal portion 252 in the second mesa portion 62 can easily be greater than the volume of the barrier metal portion 252 in the first mesa portion 61. Thus, the threshold voltage of the non-adjustment region 202 may be lower than the threshold voltage of the adjustment region 201. Also in this case, by increasing the area of the non-adjustment region 202, local current crowding can be reduced even if the turn-off of the non-adjustment region 202 is delayed to be later than that of the adjustment region 201.

In the transistor portion 70, the number of the second mesa portions 62 (refer to FIG. 3 and the like) may be greater than the number of the first mesa portions 61 (refer to FIG. 3 and the like). In this way, even if the turn-off of the non-adjustment region 202 is delayed to be later than that of the adjustment region 201, local current crowding can be reduced. In the transistor portion 70, the threshold voltage of the second mesa portion 62 may be lower than the threshold voltage of the first mesa portion 61. By adjusting the depth of the trench contact portion 17 in the first mesa portion 61 and the dose amount of each plug region, the threshold voltage of each mesa portion can be adjusted. Note that the threshold voltage of the mesa portion is a voltage at which at least one channel region in the mesa portion transits from OFF to ON.

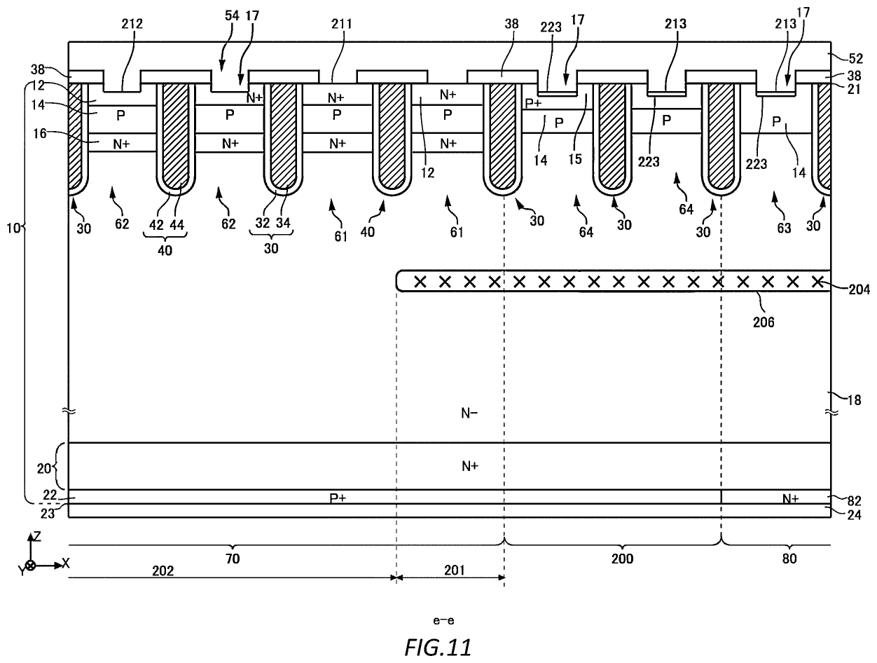

FIG. 11 shows another example of the cross section e-e. In the semiconductor device 100 of the present example, the arrangement of the lifetime adjustment region 206, the adjustment region 201, the non-adjustment region 202, the first mesa portion 61, and the second mesa portion 62 is different compared to the structure described in FIG. 3. Other structures are similar to those of the semiconductor device 100 in any aspect described in the present specification.

In the semiconductor device 100 shown in FIG. 3, all of the mesa portions 60 in the adjustment region 201 is the first mesa portion 61, and all of the mesa portions 60 of the non-adjustment region 202 is the second mesa portion 62. In the semiconductor device 100 of the present example, the first mesa portion 61 is included in the non-adjustment region 202. The mesa portion 60 other than the first mesa portion 61 in the non-adjustment region 202 is the second mesa portion 62. All of the mesa portion 60 of the adjustment region 201 may be the first mesa portion 61.

Among the mesa portions 60 of the non-adjustment region 202, one or more mesa portions 60 that are the closest to the adjustment region 201 may be the first mesa portion 61. In the example of FIG. 11, in the non-adjustment region 202, one piece of the mesa portion 60 that is the closest to the adjustment region 201 is the first mesa portion 61. In another example, in the non-adjustment region 202, two or more mesa portions 60 that are the closest to the adjustment region 201 may be the first mesa portion 61. In addition, the first mesa portion 61 may be positioned on the boundary between the adjustment region 201 and the non-adjustment region 202.

In each example described in the present specification, the base region 14 of the diode portion 80 may have a doping concentration higher than that of the base region 14 of the transistor portion 70. In this case, even if the third contact portion 213 is the trench contact portion 17, the decrease of the injection amount of holes from the base region 14 of the diode portion 80 can be reduced.

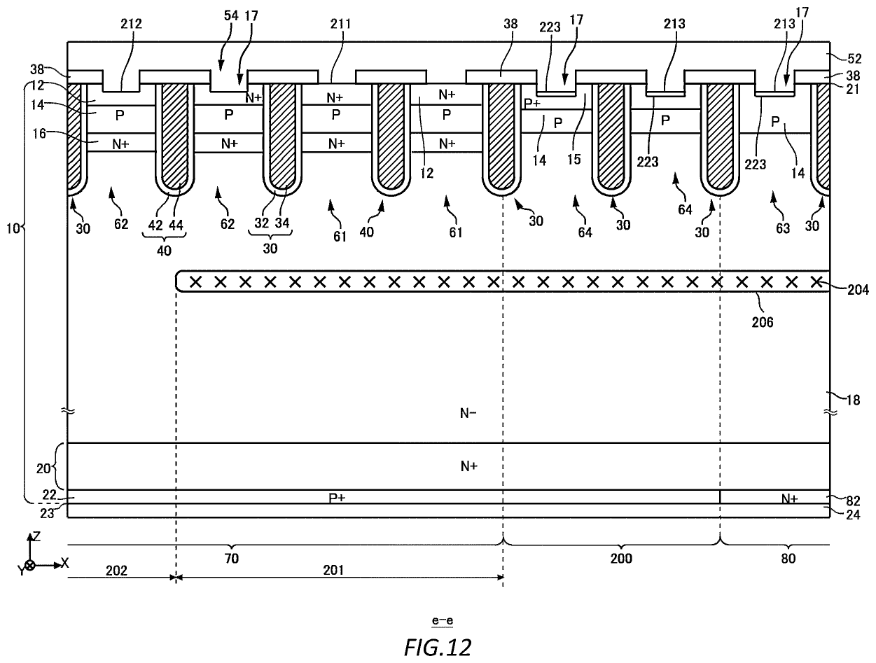

FIG. 12 shows another example of the cross section e-e. In the semiconductor device 100 of the present example, the arrangement of the lifetime adjustment region 206, the adjustment region 201, the non-adjustment region 202, the first mesa portion 61, and the second mesa portion 62 is different compared to the structure described in FIG. 3. Other structures are similar to those of the semiconductor device 100 in any aspect described in the present specification.

In the semiconductor device 100 of the present example, the second mesa portion 62 is included in the adjustment region 201. The mesa portions 60 other than the second mesa portion 62 in the adjustment region 201 is the first mesa portion 61. All of the mesa portion 60 of the non-adjustment region 202 may be the second mesa portion 62. Among the mesa portions 60 of the adjustment region 201, one or more mesa portions 60 that are the closest to the non-adjustment region 202 may be the second mesa portion 62. In the example of FIG. 12, in the adjustment region 201, one piece of the mesa portion 60 that is the closest to the non-adjustment region 202 is the second mesa portion 62. In another example, in the adjustment region 201, two or more mesa portions 60 that are the closest to the non-adjustment region 202 may be the second mesa portion 62. In addition, the second mesa portion 62 may be positioned on the boundary between the adjustment region 201 and the non-adjustment region 202.

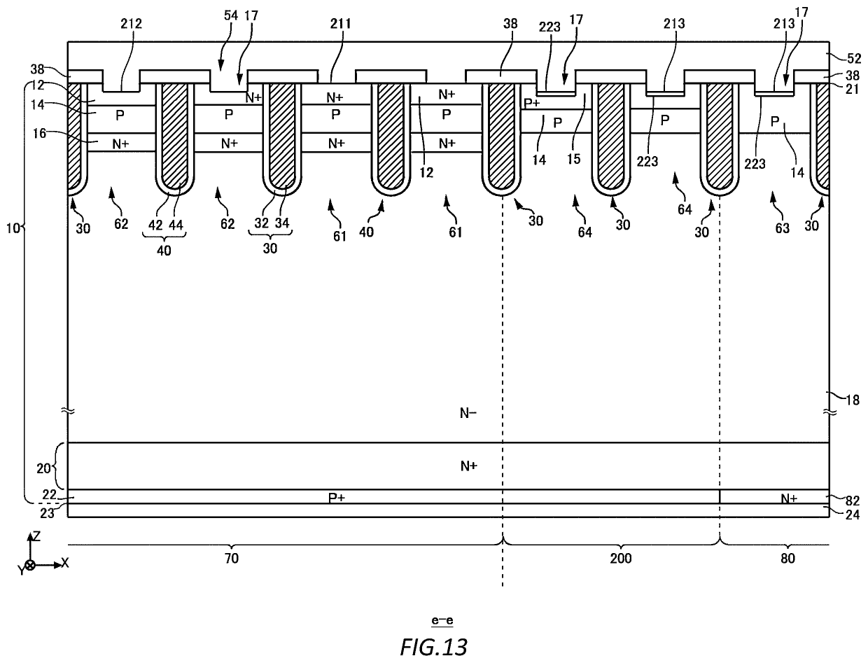

FIG. 13 shows another example of the cross section e-e. The semiconductor device 100 of the present example is different from the semiconductor device 100 described in the present specification in that it does not have the lifetime adjustment region 206, the adjustment region 201, and the non-adjustment region 202. Other structures are similar to those of the semiconductor device 100 in any aspect described in the present specification. In FIG. 13, an example obtained by deleting the lifetime adjustment region 206, the adjustment region 201, and the non-adjustment region 202 from the structure shown in FIG. 3 is shown, but the lifetime adjustment region 206, the adjustment region 201, and the non-adjustment region 202 may also be deleted in the structures shown in other drawings.

In the semiconductor device 100, a lower end of the first contact portion 211 of the first mesa portion 61 is arranged above a lower end of the second contact portion 212 of the second mesa portion 62. In this way, many contact regions 15 of the first mesa portion 61 remain, and the hole implantation amount from the first mesa portion 61 can be increased. For example, if the diode portion 80 performs a freewheeling operation, the hole implantation amount from the first mesa portion 61 in a vicinity of the diode portion 80 can be increased.

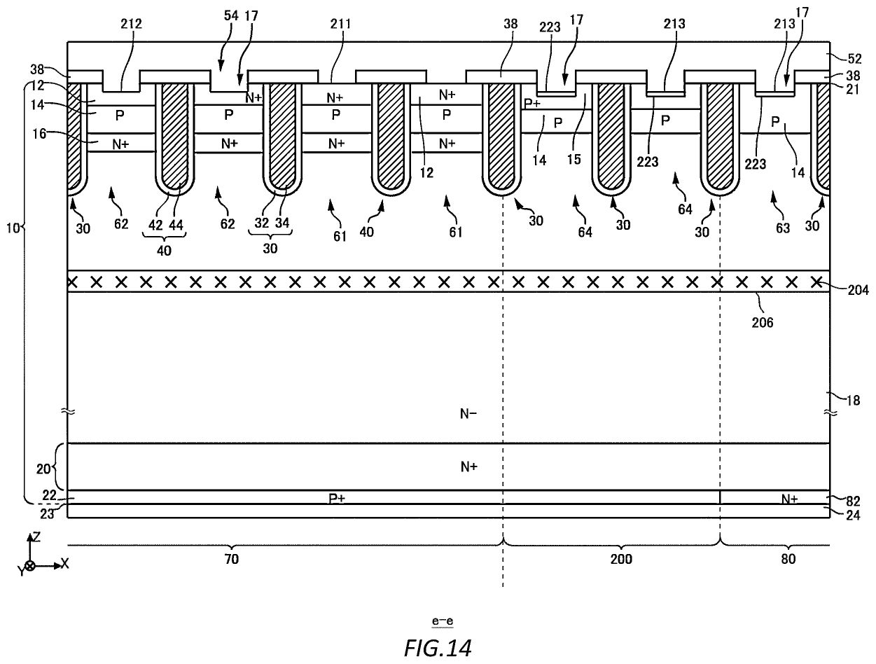

FIG. 14 shows another example of the cross section e-e. The semiconductor device 100 of the present example is different from the semiconductor device 100 described in the present specification in that the lifetime adjustment region 206 is provided in the entire transistor portion 70 in the X axis direction. Other structures are similar to those of the semiconductor device 100 in any aspect described in the present specification. In FIG. 14, in the structure shown in FIG. 3, an example in which the lifetime adjustment region 206 is arranged in the entire transistor portion 70 is shown, but the lifetime adjustment region 206 may also be arranged in the entire transistor portion 70 in the structures shown in other drawings.

Also in the semiconductor device 100 of the present example, a lower end of the first contact portion 211 of the first mesa portion 61 is arranged above a lower end of the second contact portion 212 of the second mesa portion 62. In this way, many contact regions 15 of the first mesa portion 61 remain, and the hole implantation amount from the first mesa portion 61 can be increased. For example, if the diode portion 80 performs a freewheeling operation, the hole implantation amount from the first mesa portion 61 in a vicinity of the diode portion 80 can be increased.

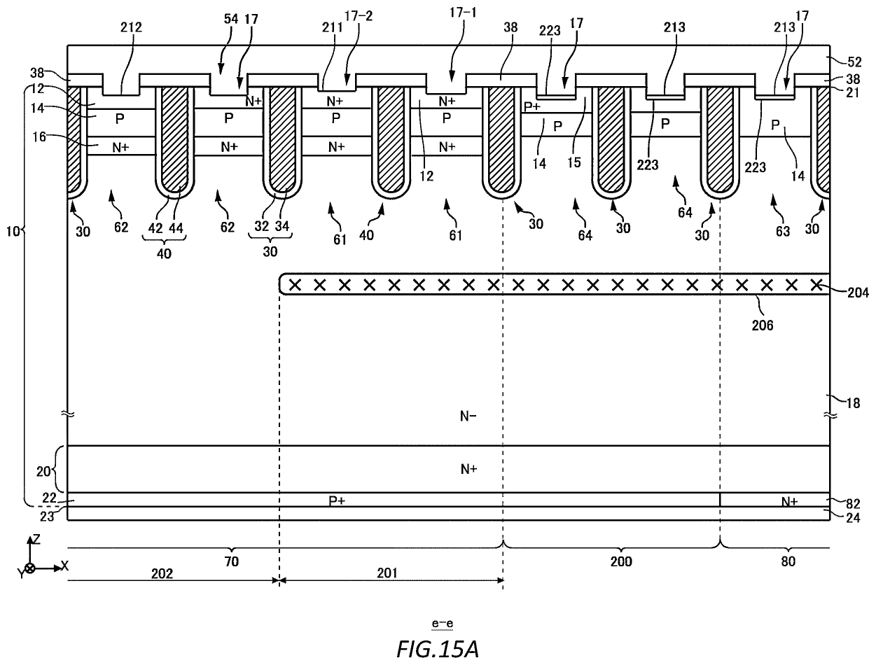

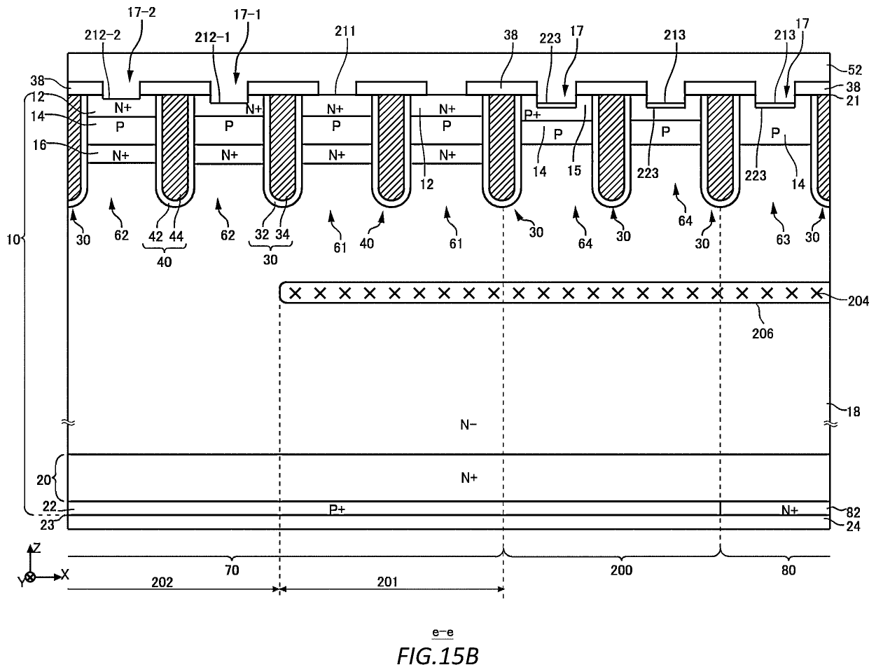

FIG. 15A shows another example of the cross section e-e. In the semiconductor device 100 of the present example, the depths of the trench contact portion 17-1 and the trench contact portion 17-2 are different compared to the structure described in FIG. 9A. Other structures are similar to those of the semiconductor device 100 in any aspect described in the present specification.

In the present example, at least one piece of the trench contact portion 17-2 of the first mesa portion 61 is provided at a position shallower than that of a trench contact portion 17-1 of a first mesa portion 61 arranged closer to the diode portion 80 than the at least one first mesa portion 61. Each trench contact portion 17 of the first mesa portion 61 may be formed at a shallower position as the trench contact portion 17 is apart farther from the diode portion 80.

FIG. 15B shows another example of the cross section e-e. In the semiconductor device 100 of the present example, the depths of the trench contact portion 17-1 and the trench contact portion 17-2 provided in the second mesa portion 62 are different compared to the structure described in FIG. 9B. Other structures are similar to those of the semiconductor device 100 in any aspect described in the present specification.

In the present example, at least one piece of the trench contact portion 17-2 of the second mesa portion 62 is provided at a position shallower than that of a trench contact portion 17-1 of a second mesa portion 62 arranged closer to the diode portion 80 than the at least one second mesa portion 62. Each trench contact portion 17 of second mesa portion 62 may be formed at a shallower position as the trench contact portion 17 is apart farther from the diode portion 80.

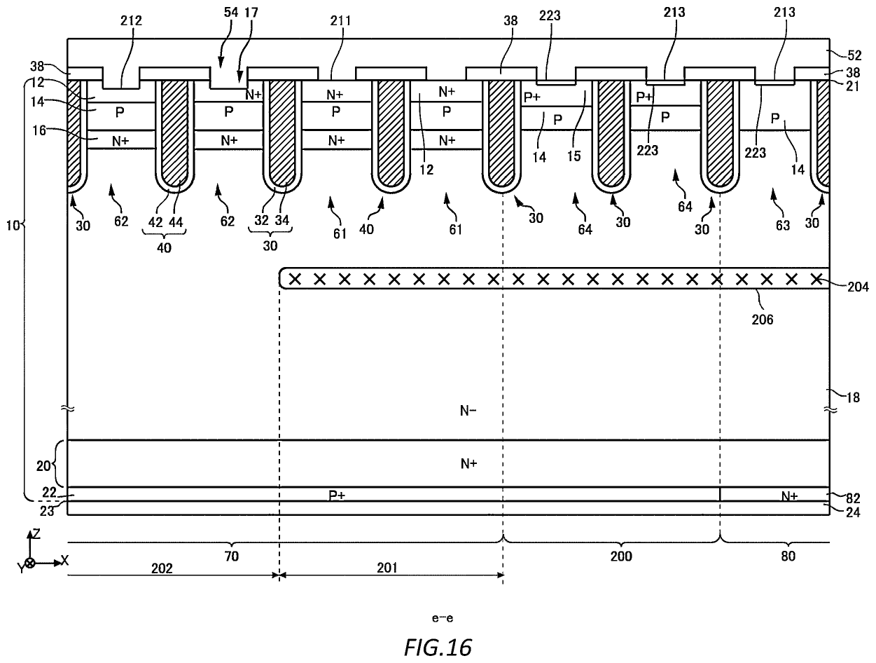

FIG. 16 shows another example of the cross section e-e. In the semiconductor device 100 of the present example, at least one piece of the lower end of the third contact portion 213 of third mesa portion 63 of the diode portion 80 is arranged above the lower end of the second contact portion 212. All lower ends of third contact portions 213 of the third mesa portion 63 of the diode portion 80 may be arranged above the lower end of the second contact portion 212. The lower end of the third contact portion 213 may be arranged at a height position that is the same as that of the upper surface 21 of the semiconductor substrate 10. The fourth mesa portion 64 of the boundary region 200 may have a third contact portion 213 similar to that of the third mesa portion 63. Other structures are similar to those of the semiconductor device 100 in any aspect described in the present specification.

The lower end of the third contact portion 213 may be arranged at a depth position that is the same as that of the lower end of the first contact portion 211. The lower end of the third contact portion 213 may be arranged above or below the lower end of the first contact portion 211.

In the present example, because the third contact portion 213 is formed to be shallow, many base regions 14 of the third mesa portion 63 can remain. Thus, the hole implantation amount in the diode portion 80 can be increased, to reduce the forward voltage. In addition, even if a barrier metal is provided in the semiconductor device 100, an amount of a barrier metal in the third contact portion 213 can be reduced. In this way, the occlusion of hydrogen in the third contact portion 213 can be reduced, to maintain the injection amount of hydrogen to the transistor portion 70 via the third contact portion 213. In this way, the decrease of the threshold voltage of the transistor portion 70 can be reduced.

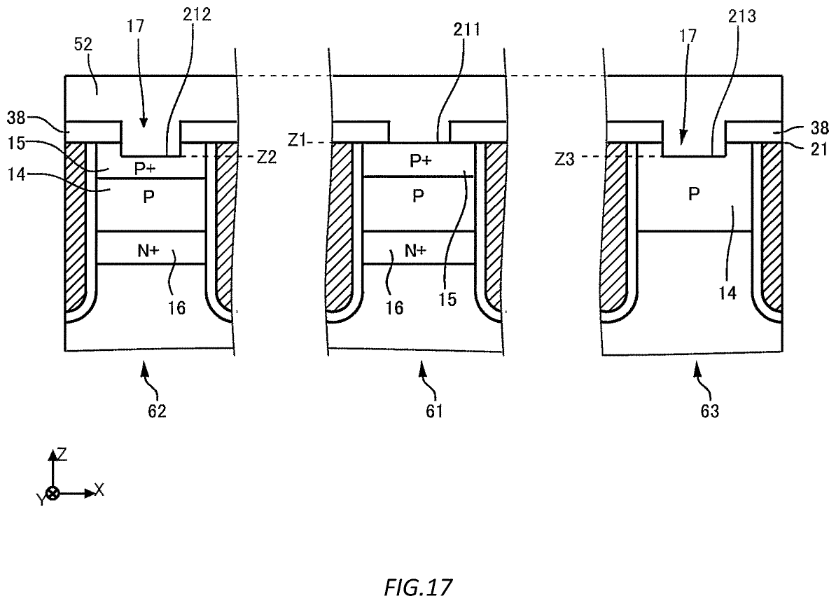

FIG. 17 is an enlarged view of a vicinity of the first mesa portion 61, the second mesa portion 62, and the third mesa portion 63 shown in FIG. 5. In FIG. 17, each of the first mesa portion 61, the second mesa portion 62, and the third mesa portion 63 is indicated one by one, and regions between the respective mesa portions are omitted.

The emitter electrode 52 of the present example is different from that of FIG. 6B in that it does not have the barrier metal portion 252 in a portion in contact with the semiconductor substrate 10. In addition, the first contact portion 211, the second contact portion 212, and the third contact portion 213 are different from those of FIG. 6B in that they do not have the first plug region 221, the second plug region 222, and the third plug region 223. Other structures are similar to those of the semiconductor device 100 in any aspect described in the present specification. In this way, the forward voltage can be reduced by not providing the trench contact portion 17 to the first mesa portion 61 of the transistor portion 70. As described above, according to the present example, the hole injection in the transistor portion 70 in a vicinity of the diode portion 80 is adjusted and the decrease of the withstand capability is reduced, and therefore a trade-off between a reverse recovery loss and the forward voltage can be adjusted.

While the present invention has been described by way of the embodiments, the technical scope of the present invention is not limited to the scope described in the above-described embodiments. It is apparent to persons skilled in the art that various alterations or improvements can be made to the above-described embodiments. It is also apparent from the described scope of the claims that the embodiments added with such alterations or improvements can be included the technical scope of the present invention.

The operations, procedures, steps, stages, or the like of each process performed by a device, system, program, and method shown in the claims, embodiments, or diagrams can be realized in any order as long as the order is not indicated by “prior to,” “before,” or the like and as long as the output from a previous process is not used in a later process. Even if the process flow is described using phrases such as “first” or “next” in the claims, the specification, or the drawings for the sake of convenience, it does not necessarily mean that the process must be performed in this order.

What is claimed is:

1. A semiconductor device, comprising: a semiconductor substrate having an upper surface and a lower surface; a transistor portion provided in the semiconductor substrate; and a diode portion that is provided in the semiconductor substrate and arranged side by side with the transistor portion in a first direction, wherein:
each of the transistor portion and the diode portion includes:
a metal electrode that is provided above the upper surface of the semiconductor substrate, and includes a barrier metal portion and an upper portion that is provided above the barrier metal portion and formed of a material different from that of the barrier metal portion;
a plurality of trench portions that are provided from the upper surface of the semiconductor substrate to an inside thereof and arranged side by side in the first direction; and
a plurality of mesa portions, each of which is a portion of the semiconductor substrate, which is sandwiched by two of the trench portions in the first direction;
the transistor portion includes:
a first contact portion in which a first mesa portion among the plurality of mesa portions and the metal electrode are in contact with each other; and
a second contact portion in which a second mesa portion among the plurality of mesa portions, which is arranged farther apart from the diode portion than the first mesa portion, and the metal electrode are in contact with each other; and
a lower end of the first contact portion is arranged above a lower end of the second contact portion.

2. The semiconductor device according to claim 1, wherein the barrier metal portion includes titanium.

3. The semiconductor device according to claim 2, wherein the barrier metal portion has a titanium nitride layer.

4. The semiconductor device according to claim 1, wherein a volume of the barrier metal portion in one piece of the second mesa portion is greater than a volume of the barrier metal portion in one piece of the first mesa portion.

5. The semiconductor device according to claim 1, wherein the second mesa portion has:
an emitter region of a first conductivity type exposed on the upper surface of the semiconductor substrate;
a contact region of a second conductivity type exposed on the upper surface of the semiconductor substrate; and
a second plug region of a second conductivity type that is provided to be in contact with the lower end of the second contact portion and having a doping concentration higher than that of the contact region.

6. The semiconductor device according to claim 5, wherein the first mesa portion has:
the emitter region;
the contact region; and
a first plug region of a second conductivity type that is provided to be in contact with the lower end of the first contact portion and having a doping concentration higher than that of the contact region, and
the second plug region is provided to a region that is lower than the first plug region.

7. The semiconductor device according to claim 6, wherein a dose amount of the first plug region and a dose amount of the second plug region are the same.

8. The semiconductor device according to claim 5, wherein
in the second mesa portion, a longitudinal length in a second direction that is different from the first direction in a top view is included, and the emitter region and the contact region are arranged alternately along the second direction; and
the second plug region is provided in any cross section that is perpendicular to the second direction and passes through the contact region.

9. The semiconductor device according to claim 8, wherein the second plug region is not provided in any cross section that is perpendicular to the second direction and passes through the emitter region.

10. The semiconductor device according to claim 6, wherein
in the first mesa portion, a longitudinal length in a second direction that is different from the first direction in a top view is included, and the emitter region and the contact region are arranged alternately along the second direction; and
the first plug region is provided in any cross section that is perpendicular to the second direction and passes through the contact region.

11. The semiconductor device according to claim 10, wherein the first plug region is not provided in any cross section that is perpendicular to the second direction and passes through the emitter region.

12. The semiconductor device according to claim 1, wherein
the second mesa portion includes a trench contact portion in which the metal electrode is provided inside the semiconductor substrate; and
the second contact portion is a region on the trench contact portion, in which the second mesa portion and the metal electrode are in contact with each other.

13. The semiconductor device according to claim 1, wherein the lower end of the first contact portion is arranged on the upper surface of the semiconductor substrate.

14. The semiconductor device according to claim 1, wherein
the diode portion has a third contact portion in which a third mesa portion among the plurality of mesa portions and the metal electrode are in contact with each other; and
the lower end of the first contact portion is arranged above a lower end of the third contact portion.

15. The semiconductor device according to claim 1, wherein
the diode portion has a third contact portion in which a third mesa portion among the plurality of mesa portions and the metal electrode are in contact with each other; and
the lower end of the third contact portion is arranged above a lower end of the second contact portion.

16. The semiconductor device according to claim 1, wherein
the diode portion has a third contact portion in which a third mesa portion among the plurality of mesa portions and the metal electrode are in contact with each other; and
the lower end of the third contact portion is arranged at a depth position that is the same as that of the lower end of the second contact portion.

17. The semiconductor device according to claim 14, wherein the third mesa portion has:
an anode region of a second conductivity type that is provided to be in contact with the upper surface of the semiconductor substrate; and
a third plug region of a second conductivity type that is provided to be in contact with the lower end of the third contact portion and having a doping concentration higher than that of the anode region.

18. The semiconductor device according to claim 5, wherein
the mesa portion of the transistor portion has a base region of a second conductivity type that is arranged below the emitter region; and
the mesa portion of the diode portion has an anode region of a second conductivity type that is provided to be in contact with the upper surface of the semiconductor substrate and having a doping concentration lower than that of the base region.

19. The semiconductor device according to claim 1, further comprising:
in at least one of the transistor portion or the diode portion, a lifetime adjustment region that is arranged in an upper surface side of the semiconductor substrate and includes a lifetime killer for adjusting a carrier lifetime.

20. The semiconductor device according to claim 19, wherein the lifetime adjustment region is arranged below the first mesa portion.

21. The semiconductor device according to claim 19, wherein the lifetime adjustment region is provided in at least one of an area below the first mesa portion or on the diode portion.

22. The semiconductor device according to claim 19, wherein the lifetime adjustment region is provided in at least any of an area below the first mesa portion, an area below the second mesa portion, or the diode portion.

23. The semiconductor device according to claim 19, wherein the transistor portion has:
an adjustment region in which the lifetime adjustment region is provided to extend from the diode portion; and
a non-adjustment region that is arranged side by side with the adjustment region in the first direction and in which the lifetime adjustment region is not provided;
the first mesa portion and the first contact portion are arranged in the adjustment region; and
the second mesa portion and the second contact portion are arranged in the non-adjustment region.

24. The semiconductor device according to claim 23, wherein in a top view, an area of the non-adjustment region is greater than an area of the adjustment region.

25. The semiconductor device according to claim 1, wherein in the transistor portion, a number of the second mesa portions is greater than a number of the first mesa portions.

26. The semiconductor device according to claim 1, having a threshold voltage of the first mesa portion lower than a threshold voltage of the second mesa portion in the transistor portion.
